(19) United States
(12) Patent Application Publication
(10) Pub. No.: US 2026/0074662 A1
(43) Pub. Date: Mar. 12, 2026

(54) LINEARIZED AMPLIFIER CIRCUITS WITH DIFFERENTLY DRAIN-BIASED FIELD EFFECT TRANSISTORS

(71) Applicant: Skyworks Solutions, Inc., Irvine, CA (US)

(72) Inventors: Yu Zhu, Wellesley, MA (US); Oleksiy Klimashov, Burlington, MA (US); Alan John Harrison, Manotick (CA); Dylan Charles Bartle, Arlington, MA (US); Guillaume Alexandre Blin, Carlisle, MA (US)

(21) Appl. No.: 19/323,990

(22) Filed: Sep. 9, 2025

Related U.S. Application Data
(60) Provisional application No. 63/692,922, filed on Sep. 10, 2024.
(60) Provisional application No. 63/692,960, filed on Sep. 10, 2024.

(51) Int. Cl. H03F 3/24; H04B 1/04

(52) U.S. Cl. CPC H03F 3/245; H03F 2200/451; H04B 2001/045; H04B 1/0475

(57) ABSTRACT

Aspects of this disclosure relate to linearized radio frequency amplifiers. A radio frequency amplifier can include first and second field effect transistors configured to receive a radio frequency input signal and provide first and second intermediate amplified signals, respectively. The first field effect transistor can have a first source and a first drain electrically biased at a first drain bias voltage and the second field effect transistor can have a second source and a second drain electrically biased at a second drain bias voltage different from the first drain bias voltage. The radio frequency amplifier can be configured to generate a combined output signal comprising the first and second intermediate amplified signal.

### CROSS REFERENCE TO PRIORITY APPLICATIONS

Any and all applications for which a foreign or domestic priority claim is identified in the Application Data Sheet as filed with the present application are hereby incorporated by reference under 37 C.F.R. § 1.57.

### BACKGROUND

### Field

Embodiments of the invention relate to electronic systems, and in particular, to radio frequency electronics.

### Description of Related Technology

Radio frequency (RF) communication systems can be used for transmitting and/or receiving signals of a wide range of frequencies. For example, an RF communication system can be used to wirelessly communicate RF signals in a frequency range of about 30 kHz to 300 GHz, such as in the range of about 400 MHz to about 7.125 GHz for Frequency Range 1 (FR1) of the Fifth Generation (5G) communication standard or in the range of about 24.250 GHz to about 71.000 GHz for Frequency Range 2 (FR2) of the 5G communication standard.

Examples of RF communication systems include, but are not limited to, mobile phones, tablets, base stations, network access points, customer-premises equipment (CPE), laptops, and wearable electronics.

### SUMMARY

In some aspects, the techniques described herein relate to a radio frequency amplifier including: a first field effect transistor configured to receive a radio frequency input signal and provide a first intermediate amplified signal on a first output of the first field effect transistor, the first field effect transistor having a first source and a first drain electrically biased at a first drain bias voltage with respect to the first source; a second field effect transistor configured to receive the radio frequency input signal and provide a second intermediate amplified signal on a second output of the second field effect transistor, the second field effect transistor having a second source and a second drain electrically biased at a second drain bias voltage different from the first drain bias voltage; and an output port coupled to first output and to the second output to provide a combined output signal in response to first intermediate amplified signal and the second intermediate amplified signal.

In some aspects, the techniques described herein relate to a radio frequency amplifier, wherein a first gate of the first field effect transistor and a second gate of the second field effect transistor are biased at a common gate voltage with respect to the first and second sources, respectively.

In some aspects, the techniques described herein relate to a radio frequency amplifier, wherein a difference between the first and second drain bias voltages is equal to a predetermined offset drain voltage.

In some aspects, the techniques described herein relate to a radio frequency amplifier, where in one or both the first drain bias voltage and the offset drain voltage are configured to reduce a third order transconductance of the radio frequency amplifier compared to a third order transconductance of the first and second field effect transistor.

In some aspects, the techniques described herein relate to a radio frequency amplifier, wherein the offset drain voltage is constant during operation of the radio frequency amplifier.

In some aspects, the techniques described herein relate to a radio frequency amplifier, wherein variation of the amplitude of a third order intermodulation frequency component of the combined output signal with respect to variation of the common gate bias voltage includes a dip having a minimum.

In some aspects, the techniques described herein relate to a radio frequency amplifier, wherein the minimum includes an absolute minimum within an operational range of the common gate bias voltage.

In some aspects, the techniques described herein relate to a radio frequency amplifier, wherein a first source the first field effect transistor and a second source of the second field effect transistor are electrically connected to a common reference voltage.

In some aspects, the techniques described herein relate to a radio frequency amplifier, wherein the common reference voltage includes a ground potential.

In some aspects, the techniques described herein relate to a radio frequency amplifier, wherein the combined output signal is a sum of the first and second intermediate amplified signals.

In some aspects, the techniques described herein relate to a radio frequency amplifier, wherein a first source of the first field effect transistor and a second source of the second field effect transistor are electrically coupled to the output port.tra

In some aspects, the techniques described herein relate to a radio frequency amplifier, wherein a first drain of the first field effect transistor and a second drain of the second field effect transistor are electrically coupled to the output port.

In some aspects, the techniques described herein relate to a radio frequency amplifier, wherein the radio frequency input signal is received through an input port capacitively coupled to the first gate of the first field effect transistor and the second gate of the second field effect transistor.

In some aspects, the techniques described herein relate to a radio frequency amplifier wherein the first field effect transistor is substantially identical to the second field effect transistor.

In some aspects, the techniques described herein relate to a radio frequency amplifier, wherein at least one parameter of the first field effect transistor is different from that of the second field effect transistor.

In some aspects, the techniques described herein relate to a radio frequency amplifier, wherein transconductance gain of the first field effect transistor is different from that of the second field effect transistor.

In some aspects, the techniques described herein relate to a radio frequency amplifier, wherein the first and second transistors include junction field effect transistors.

In some aspects, the techniques described herein relate to a radio frequency amplifier, wherein the first and second transistors include metal oxide semiconductor junction field effect transistors.

In some aspects, the techniques described herein relate to a radio frequency front-end system including the radio frequency amplifier.

In some aspects, the techniques described herein relate to a mobile device including the radio frequency front-end system.

In some aspects, the techniques described herein relate to a radio frequency amplifier, wherein the first and second field effect amplifiers are connected in a parallel configuration.

In some aspects, the techniques described herein relate to a mobile device including: a radio frequency amplifier including: a first field effect transistor configured to receive a radio frequency input signal and provide a first intermediate amplified signal on a first output of the first field effect transistor, the first field effect transistor having a first source and a first drain electrically biased at a first drain bias voltage with respect to the first source; a second field effect transistor configured to receive the radio frequency input signal and provide a second intermediate amplified signal on a second output of the second field effect transistor, the second field effect transistor having a second source and a second drain electrically biased at a second drain bias voltage different from the first drain bias voltage; and an output port coupled to first output and to the second output to provide a combined output signal in response to first intermediate amplified signal and the second intermediate amplified signal.

In some aspects, the techniques described herein relate to a radio frequency amplifier wherein a first gate of the first field effect transistor and a second gate of the second field effect transistor are biased at a common gate voltage with respect to the first and second sources, respectively.

In some aspects, the techniques described herein relate to a radio frequency amplifier including: a first field effect transistor configured to receive a radio frequency input signal and provide a first intermediate amplified signal on a first output of the first field effect transistor, the first field effect transistor having a first source and a first gate electrically biased at a first gate bias voltage with respect to the first source; a second field effect transistor configured to receive the radio frequency input signal and provide a second intermediate amplified signal on a second output of the second field effect transistor, the second field effect transistor having a second source and a second gate electrically biased at a second gate bias voltage different from the first gate bias voltage; and an output port coupled to first output and to the second output to provide a combined output signal in response to first intermediate amplified signal and the second intermediate amplified signal.

In some aspects, the techniques described herein relate to a radio frequency amplifier wherein a difference between the first gate bias voltage and the second gate bias voltage is equal to an offset gate voltage configured to reduce the amplitude of a third order nonlinear frequency component of the combined output signal with respect to the respective amplitude of a third order nonlinear frequency component of the first or second intermediate amplified signal.

In some aspects, the techniques described herein relate to a radio frequency amplifier wherein a difference between the first and second gate bias voltages is equal to an offset gate voltage configured to reduce a third order transconductance of the radio frequency amplifier compared to a third order transconductance of the first and second field effect transistor.

In some aspects, the techniques described herein relate to a radio frequency amplifier wherein the offset gate voltage is constant during operation of the radio frequency amplifier.

In some aspects, the techniques described herein relate to a radio frequency amplifier wherein variation of the amplitude of a third order intermodulation frequency component of the combined output signal with respect to variation of the first gate bias voltage includes a dip having a minimum.

In some aspects, the techniques described herein relate to a radio frequency amplifier wherein the minimum includes an absolute minimum within an operational range for the first gate bias voltage.

In some aspects, the techniques described herein relate to a radio frequency amplifier wherein the offset gate voltage is configured such that third derivative of transconductance gain of the first field effect transistor and third derivative of transconductance gain of the second field effect transistor have opposite signs.

In some aspects, the techniques described herein relate to a radio frequency amplifier wherein a first source the first field effect transistor and a second source of the second field effect transistor are electrically connected to a common reference voltage.

In some aspects, the techniques described herein relate to a radio frequency amplifier wherein the common reference voltage includes a ground potential.

In some aspects, the techniques described herein relate to a radio frequency amplifier wherein the combined output signal is a sum of the first and second intermediate amplified signals.

In some aspects, the techniques described herein relate to a radio frequency amplifier wherein a first source of the first field effect transistor and a second source of the second field effect transistor are electrically coupled to the output port.

In some aspects, the techniques described herein relate to a radio frequency amplifier wherein a first drain of the first field effect transistor and a second drain of the second field effect transistor are electrically coupled to the output port.

In some aspects, the techniques described herein relate to a radio frequency amplifier, wherein the first gate of the first field effect transistor is capacitively coupled to the input port and the second gate of the second field effect transistor is capacitively coupled to the input port.

In some aspects, the techniques described herein relate to a radio frequency amplifier wherein the first field effect transistor is substantially identical to the second field effect transistor.

In some aspects, the techniques described herein relate to a radio frequency amplifier wherein at least one parameter of the first field effect transistor is different from that of the second field effect transistor.

In some aspects, the techniques described herein relate to a radio frequency amplifier wherein transconductance gain of the first field effect transistor is different from that of the second field effect transistor.

In some aspects, the techniques described herein relate to a radio frequency amplifier wherein the first and second transistors include junction field effect transistors.

In some aspects, the techniques described herein relate to a radio frequency amplifier wherein the first and second transistors include metal oxide semiconductor junction field effect transistors.

In some aspects, the techniques described herein relate to a radio frequency front-end system including the radio frequency amplifier.

In some aspects, the techniques described herein relate to a mobile device including the radio frequency front-end system.

In some aspects, the techniques described herein relate to a radio frequency amplifier wherein the first and second field effect amplifiers are connected in a parallel configuration.

In some aspects, the techniques described herein relate to a mobile device including: an antenna; and a radio frequency module including an amplifier, the amplifier including a first field effect transistor configured to receive a radio frequency input signal and provide a first intermediate amplified signal, the first field effect transistor having a first source and a first gate electrically biased at a first gate bias voltage with respect to the first source, a second field effect transistor configured to receive the radio frequency input signal and provide a second intermediate amplified signal, the second field effect transistor having a second source and a second gate electrically biased at a second gate bias voltage different from the first gate bias voltage, and the amplifier further including an output port coupled to first intermediate amplified signal and to the second intermediate amplified signal to generate a combined output signal.

In some aspects, the techniques described herein relate to a mobile device wherein a difference between the first and second gate bias voltages is equal to an offset gate voltage configured to reduce the amplitude of a third order nonlinear frequency component of the combined output signal with respect to the respective amplitude of a third order nonlinear frequency component of the first or second intermediate amplified signal.

### BRIEF DESCRIPTION OF THE DRAWINGS

FIG. 1 is a schematic diagram of one example of a communication network.

FIG. 2A is a schematic diagram of one example of a communication link using carrier aggregation.

FIG. 2B illustrates various examples of uplink carrier aggregation for the communication link of FIG. 2A.

FIG. 2C illustrates various examples of downlink carrier aggregation for the communication link of FIG. 2A.

FIG. 3A is a block diagram of a power amplifier system having at least one transconductance stage.

FIG. 3B is a schematic diagram of a portion of a transconductance stage of the power amplifier system of FIG. 1.

FIG. 4A is a schematic diagram of an example of a single-transistor amplifier circuit.

FIG. 4B qualitatively illustrates variation of drain current with respect to gate-source voltage of a field effect transistor (FET) used in the amplifier circuit shown in FIG. 4A.

FIG. 4C qualitatively illustrates an example behavior of radio frequency (RF) power output by the amplifier circuit shown in FIG. 4A as a function of input RF power.

FIG. 5 shows measured and calculated variation of RF power at the fundamental frequency and third order intermodulation RF power (P_{out-IM3}) output by the single-transistor amplifier circuit shown in FIG. 4A, with respect to gate voltage (V_{g}) at fixed drain-source voltage (V_{ds}),

FIGS. 6A-6B show measured and calculated variation of input and output third order intercept points, IIP3 and OIP3, with respect to gate voltage (V_{g}) corresponding to the P_{out-IM3}−V_{g} curves plotted in FIG. 5.

FIG. 7A is a schematic diagram of two commonly fed single-transistor amplifier circuits comprising field effect transistors (FETs) having different gate bias voltages.

FIG. 7B shows calculated variation of third order transconductances (gₘ₃'s) of each of the FET shown in FIG. 7A, at a fixed drain-source voltage (V_{ds}), with respect to the gate voltage (V_{g}) of one the FETs.

FIG. 8A is a schematic diagram of a dual-transistor amplifier circuit with reduced third other transconductance.

FIG. 8B shows calculated variation of third order transconductance (gₘ₃) provided by the amplifier circuit of FIG. 8A with respect to gate voltage (V_{g}) of one of the FETs. The third order transconductances provided by the single-transistor amplifier circuits of FIG. 7A are also shown for comparison.

FIG. 9 shows calculated variation of third order intermodulation RF power (P_{out-IM3}) with respect to gate voltage (V_{g}) at a fixed drain-source voltage (V_{ds}), for the dual-transistor amplifier circuit shown in FIG. 8A and one of the single-transistor amplifier circuits shown in FIG. 7A.

FIGS. 10A-10B show calculated variation of input and output third order intercept points, IIP3 and OIP3, with respect to gate voltage (V_{g}) at a fixed drain-source voltage (V_{ds}), for the dual-transistor amplifier circuit shown in FIG. 8A and one of the single-transistor amplifier circuits shown in FIG. 7A.

FIG. 11 shows calculated variation of fundamental output RF power and third order intermodulation RF power (P_{out-IM3}) with respect to gate voltage (V_{g}), at a fixed drain-source voltage (V_{ds}), measured for seven copies of one of the single-transistor amplifier circuits shown in FIG. 7A, where each amplifier circuit uses a different one of seven FETs co-fabricated on a common wafer (shown at right side of the plot). The calculated variation of third order intermodulation RF power (P_{out-IM3}) generated by the dual-transistor amplifier circuit shown in FIG. 8A (from FIG. 9), is superimposed on the plot for comparison.

FIG. 12 shows calculated variation of third order intermodulation RF power (P_{out-IM3}) with respect to pinch-off voltage (Vₚ) of the FETs at a fixed drain-source voltage (V_{ds}), for the dual-transistor amplifier circuit shown in FIG. 8A and one of the single-transistor amplifier circuits shown in FIG. 7A.

FIGS. 13A-13B show calculated variation of input and output third order intercept points, IIP3 and OIP3, with respect to with respect to pinch-off voltage (Vₚ) of the FETs, for the dual-transistor amplifier circuit shown in FIG. 8A and one of the single-transistor amplifier circuits shown in FIG. 7A.

FIG. 14 shows measured variation of transconductance (Gm) provided by a FET, with respect to the gate voltage (V_{g}), for five different values of drain voltage (V_{d}).

FIG. 15 shows measured variation of third transconductance (Gm3) provided by an FET, with respect to the gate voltage (V_{g}), for five different values of drain voltage (V_{d}).

FIG. 16 shows calculated variation of third order intermodulation RF power (P_{out-IM3}) with respect to gate voltage (V_{g}) for three different values of drain voltage (V_{d}).

FIG. 17A is a schematic diagram of a dual-transistor amplifier circuit with reduced third order transconductance having two FETs biased at different drain voltages.

FIG. 17B shows calculated variation of third order transconductance (Gm3) provided by the amplifier circuit of FIG. 17A with respect to a common gate voltage (Vg) where the drain voltages of the two FETs are offset with respect to each other by Vd-offset. Also shown, for comparison, are third order transconductances provided by each of the FETs when their drains are disconnected, and they amplify a common single received from a common input.

FIG. 18A shows calculated variation of third order intermodulation RF power (P_{out-IM3}) with respect to gate voltage (V_{g}), for the dual-transistor circuit shown in FIG. 17A. Also shown, for comparison, are calculated variation of third order intermodulation RF power (P_{out-IM3}) generated by each FET in the dual-transistor circuit.

FIG. 18B shows calculated variation of third order intermodulation RF power (P_{out-IM3}) for the dual-transistor amplifier circuit of FIG. 17A and a single-transistor amplifier having an FET biased at an optimal drain voltage for reduced nonlinearity, with respect to gate voltage (V_{g}).

FIG. 19 is a schematic diagram of one embodiment of a mobile device.

### DETAILED DESCRIPTION OF EMBODIMENTS

The following detailed description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

The International Telecommunication Union (ITU) is a specialized agency of the United Nations (UN) responsible for global issues concerning information and communication technologies, including the shared global use of radio spectrum.

The 3rd Generation Partnership Project (3GPP) is a collaboration between groups of telecommunications standard bodies across the world, such as the Association of Radio Industries and Businesses (ARIB), the Telecommunications Technology Committee (TTC), the China Communications Standards Association (CCSA), the Alliance for Telecommunications Industry Solutions (ATIS), the Telecommunications Technology Association (TTA), the European Telecommunications Standards Institute (ETSI), and the Telecommunications Standards Development Society, India (TSDSI).

Working within the scope of the ITU, 3GPP develops and maintains technical specifications for a variety of mobile communication technologies, including, for example, second generation (2G) technology (for instance, Global System for Mobile Communications (GSM) and Enhanced Data Rates for GSM Evolution (EDGE)), third generation (3G) technology (for instance, Universal Mobile Telecommunications System (UMTS) and High Speed Packet Access (HSPA)), and fourth generation (4G) technology (for instance, Long Term Evolution (LTE) and LTE-Advanced).

The technical specifications controlled by 3GPP can be expanded and revised by specification releases, which can span multiple years and specify a breadth of new features and evolutions.

In one example, 3GPP introduced carrier aggregation (CA) for LTE in Release 10. Although initially introduced with two downlink carriers, 3GPP expanded carrier aggregation in Release 14 to include up to five downlink carriers and up to three uplink carriers. Other examples of new features and evolutions provided by 3GPP releases include, but are not limited to, License Assisted Access (LAA), enhanced LAA (eLAA), Narrowband Internet of things (NB-IoT), Vehicle-to-Everything (V2X), and High-Power User Equipment (HPUE).

3GPP introduced Phase 1 of fifth generation (5G) technology in Release 15, and introduced Phase 2 of 5G technology in Release 16. Subsequent 3GPP releases will further evolve and expand 5G technology. 5G technology is also referred to herein as 5G New Radio (NR).

5G NR supports or plans to support a variety of features, such as communications over millimeter wave spectrum, beamforming capability, high spectral efficiency waveforms, low latency communications, multiple radio numerology, and/or non-orthogonal multiple access (NOMA). Although such RF functionalities offer flexibility to networks and enhance user data rates, supporting such features can pose a number of technical challenges.

The teachings herein are applicable to a wide variety of communication systems, including, but not limited to, communication systems using advanced cellular technologies, such as LTE-Advanced, LTE-Advanced Pro, and/or 5G NR.

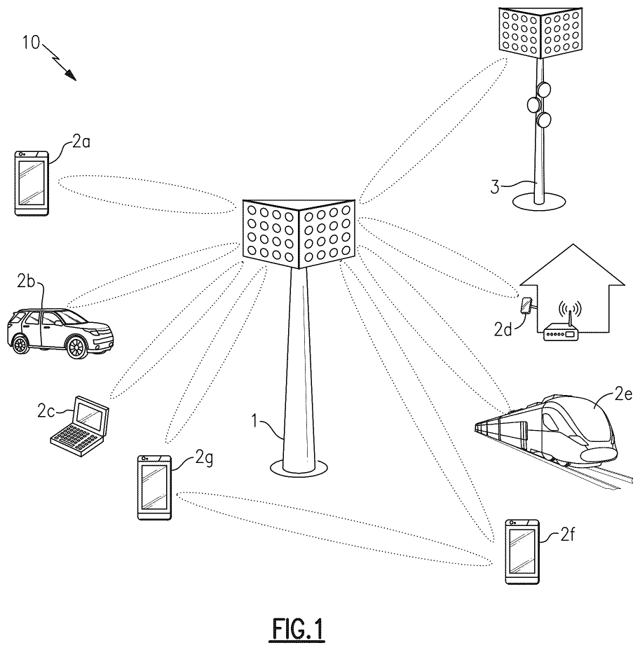

FIG. 1 is a schematic diagram of one example of a communication network 10. The communication network 10 includes a macro cell base station 1, a small cell base station 3, and various examples of user equipment (UE), including a first mobile device 2a, a wireless-connected car 2b, a laptop 2c, a stationary wireless device 2d, a wireless-connected train 2e, a second mobile device 2f, and a third mobile device 2g.

Although specific examples of base stations and user equipment are illustrated in FIG. 1, a communication network can include base stations and user equipment of a wide variety of types and/or numbers.

For instance, in the example shown, communication network 10 includes the macro cell base station 1 and the small cell base station 3. The small cell base station 3 can operate with relatively lower power, shorter range, and/or with fewer concurrent users relative to the macro cell base station 1. The small cell base station 3 can also be referred to as a femtocell, a picocell, or a microcell. Although communication network 10 is illustrated as including two base stations, the communication network 10 can be implemented to include more or fewer base stations and/or base stations of other types.

Although various examples of user equipment are shown, the teachings herein are applicable to a wide variety of user equipment, including, but not limited to, mobile phones, tablets, laptops, IoT devices, wearable electronics, customer premises equipment (CPE), wireless-connected vehicles, wireless relays, and/or a wide variety of other communication devices. Furthermore, user equipment includes not only currently available communication devices that operate in a cellular network, but also subsequently developed communication devices that will be readily implementable with the inventive systems, processes, methods, and devices as described and claimed herein.

The illustrated communication network 10 of FIG. 1 supports communications using a variety of cellular technologies, including, for example, 4G LTE and 5G NR. In certain implementations, the communication network 10 is further adapted to provide a wireless local area network (WLAN), such as WiFi. Although various examples of communication technologies have been provided, the communication network 10 can be adapted to support a wide variety of communication technologies.

Various communication links of the communication network 10 have been depicted in FIG. 1. The communication links can be duplexed in a wide variety of ways, including, for example, using frequency-division duplexing (FDD) and/or time-division duplexing (TDD). FDD is a type of radio frequency communications that uses different frequencies for transmitting and receiving signals. FDD can provide a number of advantages, such as high data rates and low latency. In contrast, TDD is a type of radio frequency communications that uses about the same frequency for transmitting and receiving signals, and in which transmit and receive communications are switched in time. TDD can provide a number of advantages, such as efficient use of spectrum and variable allocation of throughput between transmit and receive directions.

In certain implementations, user equipment can communicate with a base station using one or more of 4G LTE, 5G NR, and WiFi technologies. In certain implementations, enhanced license assisted access (eLAA) is used to aggregate one or more licensed frequency carriers (for instance, licensed 4G LTE and/or 5G NR frequencies), with one or more unlicensed carriers (for instance, unlicensed WiFi frequencies).

As shown in FIG. 1, the communication links include not only communication links between UE and base stations, but also UE to UE communications and base station to base station communications. For example, the communication network 10 can be implemented to support self-fronthaul and/or self-backhaul.

The communication links can operate over a wide variety of frequencies. In certain implementations, communications are supported using 5G NR technology over one or more frequency bands that are less than 6 Gigahertz (GHz) and/or over one or more frequency bands that are greater than 6 GHz. For example, the communication links can serve Frequency Range 1 (FR1), Frequency Range 2 (FR2), or a combination thereof. In one embodiment, one or more of the mobile devices support a HPUE power class specification.

In certain implementations, a base station and/or user equipment communicates using beamforming. For example, beamforming can be used to focus signal strength to overcome path losses, such as high loss associated with communicating over high signal frequencies. In certain embodiments, user equipment, such as one or more mobile phones, communicate using beamforming on millimeter wave frequency bands in the range of 30 GHz to 300 GHz and/or upper centimeter wave frequencies in the range of 6 GHz to 30 GHz, or more particularly, 24 GHz to 30 GHz. Cellular user equipment can communicate using beamforming and/or other techniques over a wide range of frequencies, including, for example, FR2-1 (24 GHz to 52 GHZ), FR2-2 (52 GHz to 71 GHZ), and/or FR1 (400 MHz to 7125 MHz).

Different users of the communication network 10 can share available network resources, such as available frequency spectrum, in a wide variety of ways.

In one example, frequency division multiple access (FDMA) is used to divide a frequency band into multiple frequency carriers. Additionally, one or more carriers are allocated to a particular user. Examples of FDMA include, but are not limited to, single carrier FDMA (SC-FDMA) and orthogonal FDMA (OFDMA). OFDMA is a multicarrier technology that subdivides the available bandwidth into multiple mutually orthogonal narrowband subcarriers, which can be separately assigned to different users.

Other examples of shared access include, but are not limited to, time division multiple access (TDMA) in which a user is allocated particular time slots for using a frequency resource, code division multiple access (CDMA) in which a frequency resource is shared amongst different users by assigning each user a unique code, space-divisional multiple access (SDMA) in which beamforming is used to provide shared access by spatial division, and non-orthogonal multiple access (NOMA) in which the power domain is used for multiple access. For example, NOMA can be used to serve multiple users at the same frequency, time, and/or code, but with different power levels.

Enhanced mobile broadband (eMBB) refers to technology for growing system capacity of LTE networks. For example, eMBB can refer to communications with a peak data rate of at least 10 Gbps and a minimum of 100 Mbps for each user. Ultra-reliable low latency communications (uRLLC) refers to technology for communication with very low latency, for instance, less than 2 milliseconds. uRLLC can be used for mission-critical communications such as for autonomous driving and/or remote surgery applications. Massive machine-type communications (mMTC) refers to low cost and low data rate communications associated with wireless connections to everyday objects, such as those associated with Internet of Things (IoT) applications.

The communication network 10 of FIG. 1 can be used to support a wide variety of advanced communication features, including, but not limited to, eMBB, uRLLC, and/or mMTC.

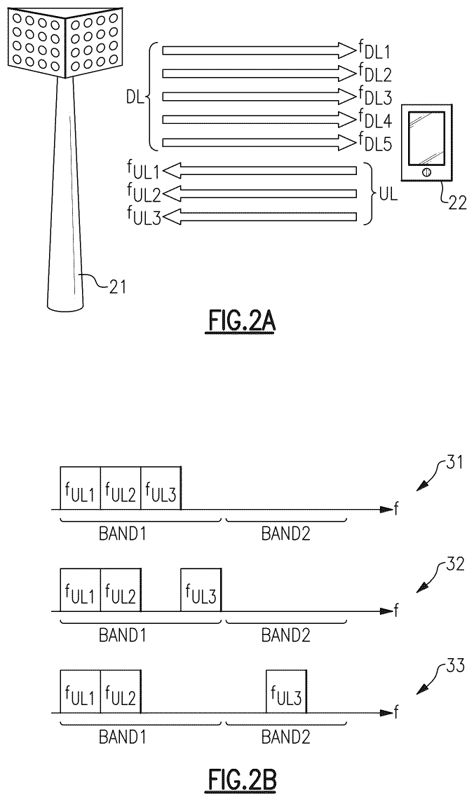

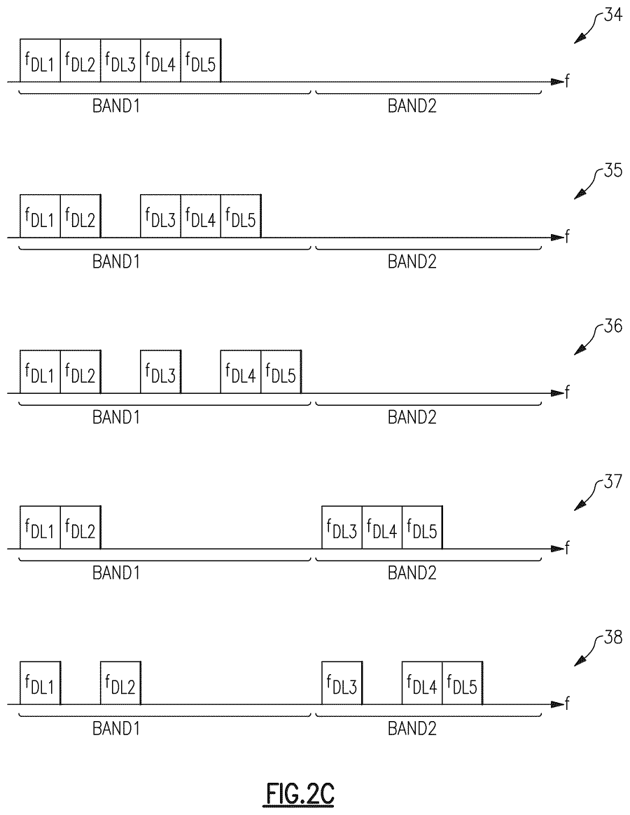

FIG. 2A is a schematic diagram of one example of a communication link using carrier aggregation. Carrier aggregation can be used to widen bandwidth of the communication link by supporting communications over multiple frequency carriers, thereby increasing user data rates and enhancing network capacity by utilizing fragmented spectrum allocations.

In the illustrated example, the communication link is provided between a base station 21 and a mobile device 22. As shown in FIG. 2A, the communications link includes a downlink channel used for RF communications from the base station 21 to the mobile device 22, and an uplink channel used for RF communications from the mobile device 22 to the base station 21.

Although FIG. 2A illustrates carrier aggregation in the context of FDD communications, carrier aggregation can also be used for TDD communications.

In certain implementations, a communication link can provide asymmetrical data rates for a downlink channel and an uplink channel. For example, a communication link can be used to support a relatively high downlink data rate to enable high speed streaming of multimedia content to a mobile device, while providing a relatively slower data rate for uploading data from the mobile device to the cloud.

In the illustrated example, base station 21 and the mobile device 22 communicate via carrier aggregation, which can be used to selectively increase bandwidth of the communication link. Carrier aggregation includes contiguous aggregation, in which contiguous carriers within the same operating frequency band are aggregated. carrier aggregation can also be non-contiguous and can include carriers separated in frequency within a common band or in different bands.

In the example shown in FIG. 2A, the uplink channel includes three aggregated component carriers f_{UL1}, f_{UL2}, and f_{UL3}. Additionally, the downlink channel includes five aggregated component carriers f_{DL1}, f_{DL2}, f_{DL3}, f_{DL4}, and f_{DL5}. Although one example of component carrier aggregation is shown, more or fewer carriers can be aggregated for uplink and/or downlink. Moreover, a number of aggregated carriers can be varied over time to achieve desired uplink and downlink data rates.

For example, a number of aggregated carriers for uplink and/or downlink communications with respect to a particular mobile device can change over time. For example, the number of aggregated carriers can change as the device moves through the communication network and/or as network usage changes over time.

FIG. 2B illustrates various examples of uplink carrier aggregation for the communication link of FIG. 2A. FIG. 2B includes a first carrier aggregation scenario 31, a second carrier aggregation scenario 32, and a third carrier aggregation scenario 33, which schematically depict three types of carrier aggregation.

The carrier aggregation scenarios 31-33 illustrate different spectrum allocations for a first component carrier f_{UL1}, a second component carrier f_{UL2}, and a third component carrier f_{UL3}. Although FIG. 2B is illustrated in the context of aggregating three component carriers, carrier aggregation can be used to aggregate more or fewer carriers. Moreover, although illustrated in the context of uplink, the aggregation scenarios are also applicable to downlink.

The first carrier aggregation scenario 31 illustrates intra-band contiguous carrier aggregation, in which component carriers that are adjacent in frequency and in a common frequency band are aggregated. For example, the first carrier aggregation scenario 31 depicts aggregation of component carriers f_{UL1}, f_{UL2}, and f_{UL3} that are contiguous and located within a first frequency band BAND1.

With continuing reference to FIG. 2B, the second carrier aggregation scenario 32 illustrates intra-band non-continuous carrier aggregation, in which two or more components carriers that are non-adjacent in frequency and within a common frequency band are aggregated. For example, the second carrier aggregation scenario 32 depicts aggregation of component carriers f_{UL1}, f_{UL2}, and f_{UL3} that are non-contiguous, but located within a first frequency band BAND1.

The third carrier aggregation scenario 33 illustrates inter-band non-contiguous carrier aggregation, in which component carriers that are non-adjacent in frequency and in multiple frequency bands are aggregated. For example, the third carrier aggregation scenario 33 depicts aggregation of component carriers f_{UL1} and f_{UL2} of a first frequency band BAND1 with component carrier f_{UL3} of a second frequency band BAND2.

FIG. 2C illustrates various examples of downlink carrier aggregation for the communication link of FIG. 2A. The examples depict various carrier aggregation scenarios 34-38 for different spectrum allocations of a first component carrier f_{DL1}, a second component carrier f_{DL2}, a third component carrier f_{DL3}, a fourth component carrier f_{DL4}, and a fifth component carrier f_{DL5}. Although FIG. 2C is illustrated in the context of aggregating five component carriers, carrier aggregation can be used to aggregate more or fewer carriers. Moreover, although illustrated in the context of downlink, the aggregation scenarios are also applicable to uplink.

The first carrier aggregation scenario 34 depicts aggregation of component carriers that are contiguous and located within the same frequency band. Additionally, the second carrier aggregation scenario 35 and the third carrier aggregation scenario 36 illustrates two examples of aggregation that are non-contiguous, but located within the same frequency band. Furthermore, the fourth carrier aggregation scenario 37 and the fifth carrier aggregation scenario 38 illustrates two examples of aggregation in which component carriers that are non-adjacent in frequency and in multiple frequency bands are aggregated. As a number of aggregated component carriers increases, a complexity of possible carrier aggregation scenarios also increases.

With reference to FIGS. 2A-2C, the individual component carriers used in carrier aggregation can be of a variety of frequencies, including, for example, frequency carriers in the same band or in multiple bands. Additionally, carrier aggregation is applicable to implementations in which the individual component carriers are of about the same bandwidth as well as to implementations in which the individual component carriers have different bandwidths.

Certain communication networks allocate a particular user device with a primary component carrier (PCC) or anchor carrier for uplink and a PCC for downlink. Additionally, when the mobile device communicates using a single frequency carrier for uplink or downlink, the user device communicates using the PCC. To enhance bandwidth for uplink communications, the uplink PCC can be aggregated with one or more uplink secondary component carriers (SCCs). Additionally, to enhance bandwidth for downlink communications, the downlink PCC can be aggregated with one or more downlink SCCs.

In certain implementations, a communication network provides a network cell for each component carrier. Additionally, a primary cell can operate using a PCC, while a secondary cell can operate using a SCC. The primary and second cells may have different coverage areas, for instance, due to differences in frequencies of carriers and/or network environment.

License assisted access (LAA) refers to downlink carrier aggregation in which a licensed frequency carrier associated with a mobile operator is aggregated with a frequency carrier in unlicensed spectrum, such as WiFi. LAA employs a downlink PCC in the licensed spectrum that carries control and signaling information associated with the communication link, while unlicensed spectrum is aggregated for wider downlink bandwidth when available. LAA can operate with dynamic adjustment of secondary carriers to avoid WiFi users and/or to coexist with WiFi users. Enhanced license assisted access (eLAA) refers to an evolution of LAA that aggregates licensed and unlicensed spectrum for both downlink and uplink. Furthermore, NR-U can operate on top of LAA/eLAA over a 5 GHz band (5150 to 5925 MHz) and/or a 6 GHz band (5925 MHz to 7125 MHz).

### RF Amplifiers in Wireless Systems

Radio frequency (RF) transmitters, such as those included in mobile wireless telephone handsets (also referred to as cellular telephones) and other portable radio transceivers, generally include one or more amplifiers. For example, a power amplifier can be the final stage of a wireless transmitter circuitry. In various wireless modules, when a signal is amplified for transmission or a weak received signal is amplified for further processing, achieving linear amplification can be important. However, various factors can hamper linear operation. For example, in a transmitter of the type generally included in some types of mobile wireless telephone handsets, where the power amplifier receives the output of an upconversion mixer, the relatively large signal that such a mixer typically outputs can drive the power amplifier into nonlinear operation. Increasing power amplifier current is one technique for promoting linear operation in such a transmitter, but it does not work well in all instances.

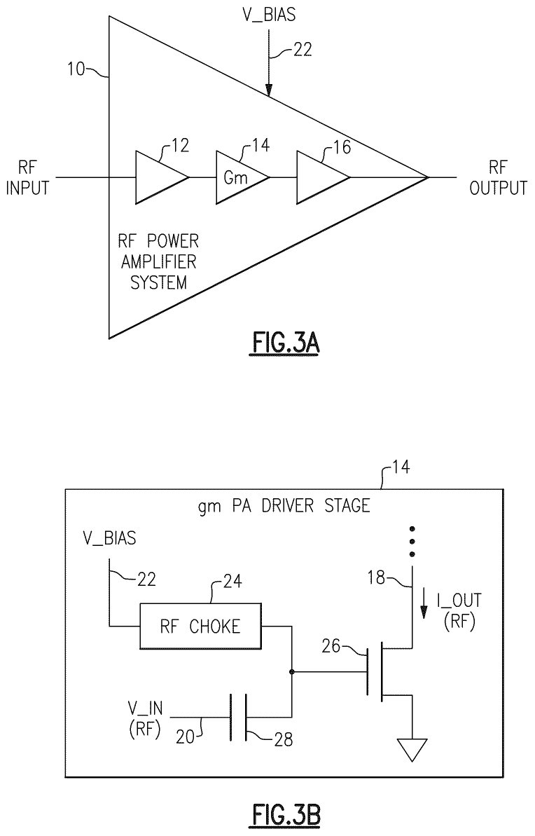

As illustrated in FIGS. 3A-3B, in a transmitter of the type generally included in some types of mobile wireless telephone handsets, the power amplifier 10 typically comprises several amplifier driver stages or sections 12, 14, 16, etc., at least one of which, such as amplifier driver stage 14, comprises a transconductance (Gₘ) amplifier that outputs a radio frequency (RF) current signal 18 (I_OUT) in response to an RF input voltage signal 20 (V_IN). The gain of power amplifier 10 can be controlled by controlling the bias voltage signal 22 (V_BIAS), which is provided via an RF choke 24. (Although not shown in FIGS. 3A-3B for purposes of clarity, circuitry in the mobile wireless telephone handset generates bias voltage signal 22 in response to various operating conditions that require adjusting transmitter output power.) As illustrated in FIG. 3B, the transconductance amplifier transistor 26 is typically a metal oxide semiconductor field-effect transistor (MOSFET) arranged in a circuit in a common-source configuration. The RF input voltage signal 20 is coupled to the gate of transistor 26 via a coupling capacitor 28. Current source circuitry that is coupled to transistor 26 is not shown for purposes of clarity but is indicated by the ellipsis (“ . . . ”) symbol. Such a MOSFET, when driven by a relatively large signal, produces a nonlinear current signal 18 as a result of transistor effects such as mobility degradation, velocity saturation, and nonlinearity of the input capacitance. It is known to design transconductance amplifiers to operate at increased current levels in an attempt to meet noise performance requirements and to some extent promote linear operation. However, increasing current alone generally cannot provide sufficient overdrive voltage at the gate-source junction to render a linear output current signal 18. A technique known as degeneration can be combined with the above-described increased current technique to further promote linearity, but degeneration hampers the use of bias voltage signal 22 as an amplifier gain control. Also, increasing current in a mobile wireless telephone handset power amplifier tends to more quickly drain the battery.

It would be desirable to promote transconductance amplifier linearity in a manner that does not consume excessive current, degrade amplifier noise performance, or sacrifice bias voltage gain controllability.

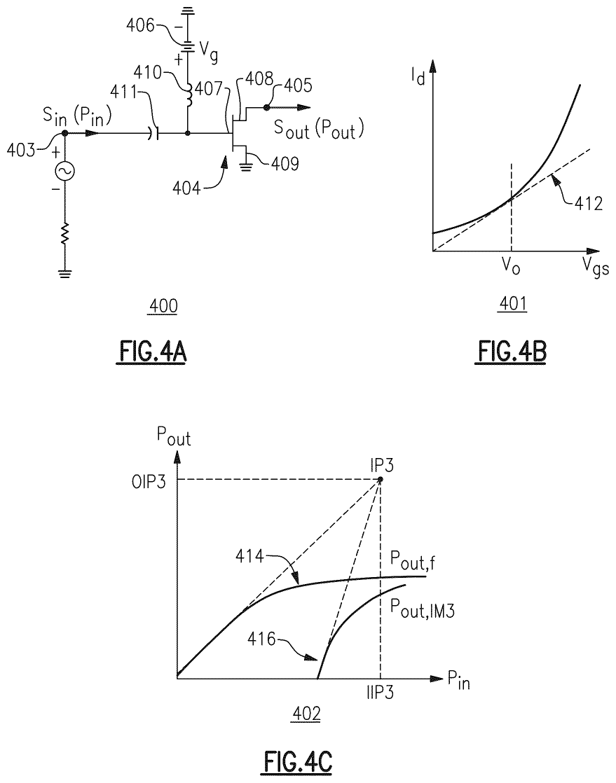

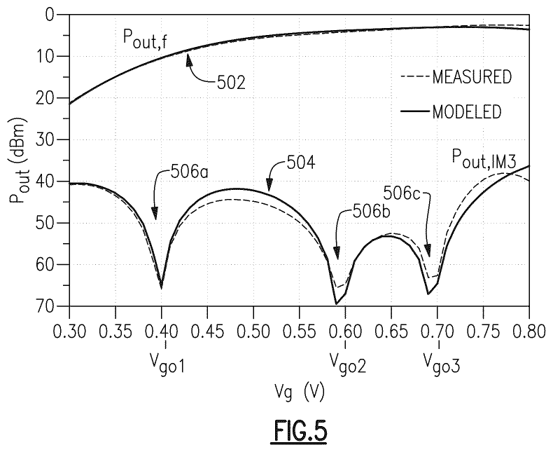

FIG. 4A schematically illustrates an amplifier circuit 400 configured to output an amplified RF signal (Sₒᵤₜ) in response to receiving an input RF signal (Sᵢₙ). In various implementations, the amplifier circuit 400 can be included in, for example, in a front-end module of a wireless system (e.g., a mobile telephone handset). In some examples, amplifier circuit 400 can be an amplifying stage in a multi-stage amplifier circuit. In some cases, a total RF power (Pₒᵤₜ) of the RF out signal (Sₒᵤₜ) can be larger than the total RF power (Pᵢₙ) of the RF input signal (Sᵢₙ) by a total gain factor (i.e., Pₒᵤₜ≈G×Pᵢₙ). In some embodiments, the amplifier circuit 400 may comprise a single transistor 404 electrically coupled to an input port (or input node) 403 through which it receives the RF input signal (Sᵢₙ) and to an output port (or node) 405 through which it outputs the output RF signal (Sₒᵤₜ), also referred to as the amplified signal. In some embodiments, the single transistor may comprise a field-effect transistor (FET) such as a junction FET (JFET), or a bipolar transistor (BJT). In the embodiment shown in FIG. 4A, the transistor 404 is a FET (e.g., a JFET), however embodiments are not so limited and the amplifier circuit 400 can include other types of transistors. In some embodiments, a gate terminal 407 (also referred to gate 407) of the FET 404 can be electrically coupled to the input port 403. In some implementations, gate 407 may be biased at a gate bias voltage (V_{g}) with respect to the source terminal 409 of the FET 404. In some examples, gate 407 can be electrically connected to a gate bias voltage source 406 configured to bias the gate 407 at a bias voltage (V_{g}). In some examples, gate 407 may be electrically connected to the gate voltage source 406 through an RF choke 410 configured to reduce or block radio frequency (RF) coupling between the bias voltage source 406 and the gate 407. In some examples, gate 407 can be capacitively coupled to the input port 403 through a coupling capacitor 411, e.g., configured to serve as a DC block. The source terminal 409 (also referred to as source 409) of the FET 404 can be connected to a reference node configured to maintain a potential of the source 409 at a reference potential. In some examples, the reference potential can be a ground potential. A drain terminal 408 of the FET 404 can be electrically coupled to the output port 405. In some implementations, the drain terminal 408 of the FET 404 can be biased at drain bias voltage (Vd).

In some embodiments, the output port of an amplifier circuit similar to the amplifier circuit 400 may be electrically coupled to the source terminal of the corresponding FET (instead of the drain terminal).

In various implementations, electrical coupling may comprise direct electrical contact, capacitive coupling, inductive coupling, or other types of electrical coupling that allow transmission of RF signals, currents, voltages at least within a frequency range that may include zero (DC).

### Distortion in Amplifier Circuits

In some embodiments, the spectrum of the output RF signal (Sₒᵤₜ) generated by the amplifier circuit 400 may comprise additional frequency components with respect to the spectrum of the RF input signal (Sᵢₙ). In some cases, these additional frequency components may be generated by a nonlinearity of one or more components of the amplifier circuit 400. For example, the transconductance gain of the FET 404 may change with respect to the gate-to-source voltage (V_{gs}) resulting in generation of additional frequency components. FIG. 4B is an I_{d}−V_{ds} plot 401 schematically illustrating an example variation of the drain current (I_{d}) with respect to V_{gs} for the single-transistor amplifier circuit 400. In some cases, transconductance (gₘ) of a single-transistor amplifier or transistor (e.g., an FET) may quantify a change in drain-source current (Ids) caused by a small change in gate-source voltage (V_{gs}) when drain-source voltage (V_{ds}) constant, and can be expressed as:

$${g}_{m} = \frac{{dI}_{ds}}{{dV}_{gs}} \qquad ( 1 )$$

As shown in FIG. 4B, due to nonlinearity of the I_{d}−V_{gs} curve for a typical transistor (e.g., an FET), transconductance (gₘ) may vary for different values of V_{gs}. In some cases, for a given V_{gs}, for example when V_{gs} is fixed at an operating gate voltage (V_{O}), gₘ can be the slope of a line 412 tangent to the I_{d}−V_{gs} curve at V_{gs}=V_{O}. Due to the nonlinearity of I_{d}−V_{gs} curve for a typical amplifier or transistor, higher order derivatives of gₘ are nonzero and can generate nonlinear frequency products and thereby distort the resulting amplified output signal (Sₒᵤₜ).

Nonlinearity of an RF amplifier may cause certain performance issues, e.g., harmonic generation, gain compression, cross modulation and intermodulation, in an RF system. In some embodiments, nonlinearity of an amplifier circuit used in a transmitter or receiver circuit of a wireless front-end system may degrade a performance of the corresponding wireless system by distorting the amplified signal and generating frequency components (e.g., intermodulation products) causing interference between adjacent wireless channels (e.g., in a carrier aggregated wireless communication link). In various examples, odd-order nonlinearities can generate frequency components that close one or more carrier frequencies and are difficult to filter. For example, third order nonlinearity can lead to third-order intermodulation distortion (IMD) that can be the dominant nonlinearity component in degrading the performance of a wireless system. In some embodiments, the third order nonlinearity of an amplifier or transistor may be quantified by a third order transconductance (gₘ₃). In some cases, gₘ₃ can be proportional to the third-order term in a Taylor series expansion of the transconductance gₘ and can be defined as the third order derivative of gₘ with respect to V_{gs} at a given value of V_{gs} (e.g., V_{gs}=V_{O}):

$${g}_{m 3} = \frac{{d}^{3} {I}_{ds}}{{{dV}_{gs}}^{3}} \qquad ( 2 )$$

Third order transconductance gₘ₃ can make significant contribution in distorting an amplified output signal generated by an FET in particular by generating third order intermodulation (IM3) frequency products close to frequencies of the input signal. Similar to gₘ, gₘ₃ may change for different values of V_{gs} thus the magnitude of P_{out-IM3} can depend on V_{gs}. In the example circuit shown the source 409 of the FET 404 is connected to ground potential, so V_{gs}=V_{g} or the gate voltage with respect to the ground potential.

FIG. 4C is a Pₒᵤₜ−Pᵢₙ plot 402 schematically illustrating an example behavior of the RF power of Sₒᵤₜ at a fundamental frequency (e.g., f that can be a frequency component in the spectrum of Sᵢₙ), labeled as P_{out,f}, and RF power of Sₒᵤₜ at a third order frequency product (e.g., third harmonic of the fundamental frequency, 3f, or an intermodulation, IM, frequency), labeled as P_{out,IM3}, plotted against input RF power (Pᵢₙ) or the RF power input power at the fundamental frequency. In some examples, RF power curve (P_{out,f},) 414 representing RF power of Sₒᵤₜ at the fundamental frequency may initially grow linearly with a slope of 1:1 and then asymptotically approach a saturated value. RF power curve (P_{out,IM3}) 416 representing RF power of Sₒᵤₜ at the third order frequency product may be initially negligible and then grow linearly with a slope 3:1. In some cases, a third order intercept point (IP3) may be defined as crossing point between a first tangent line tangent associated with the linear portion of RF power curve 414 and a second tangent line tangent associated with the linear portion of RF power curve 416. IP3 can be read off from the input power (Pᵢₙ) or output power (Pₒᵤₜ) axis, leading to input (IIP3) or output (OIP3) intercept point respectively. In some cases, IP3 (or the corresponding OIP3 or IIP3) represent the strength of the third order nonlinearity or the magnitude of P_{out-IM3}.

In some implementations, the power of the fundamental or linear component (P_{out,f}) and the third order nonlinear intermodulation component of the (P_{out,IM3}) can be expressed as:

$${P}_{out , f} ( {V}_{g} ) = 10 \times log ( 4 {G}_{m}^{2} {R}_{s} {R}_{l} ) + {P}_{in} \qquad ( 3 )$$

$${P}_{out , IM 3} ( {V}_{g} ) = 10 \times log ( 4 {G}_{m 3}^{2} {R}_{s}^{3} {R}_{l} ) + 3 {P}_{in} - 60 \qquad ( 4 )$$

In various embodiments, gₘ and/or gₘ₃ may change when a bias point of a transistor that amplifies the input RF signal changes. For example, gₘ and/or gₘ₃ may change when a voltage difference (V_{gs}) between the gate terminal and the source terminal and/or between the drain terminal and the source terminal (V_{ds}) are changes. As such, in some embodiments, gₘ and/or gₘ₃ may be controlled by adjusting one or more bias voltages applied to the transistor.

FIG. 5 shows measured and calculated variation of fundamental output RF power (P_{out,f}) and third order intermodulation RF power (P_{out,IM3}) plotted against the gate voltage (V_{g}) at fixed drain-source voltage (V_{ds}), for an example single-transistor amplifier circuit (e.g., amplifier circuit 400). Here the source terminal of the transistor (e.g., source 409) is connected to the ground potential, as such V_{gs} is labeled as V_{g} (indicating that V_{g} is substantially equal to zero). In this example, V_{ds}=V_{d}=3 Volts, the input RF signals is a single tone signal having a frequency of 0.5 GHZ, the RF power of the input signal (Pᵢₙ) is about-20 dBm, and V_{g} is varied from 0.3 volts to 0.8 volts. As indicated by P_{out,f}−V_{g} curve 502 and P_{out,IM3}−V_{g} curve 504, when V_{g} changes from 0.3 to 0.8 volts, P_{out,f} increases from a value slightly below-20 dBm at V_{g}=0.3 volts to a value of slightly above-5 dBm at V_{g}=0.8 volts, and P_{out,IM3} varies between −70 dBm and −40 dBm. In some embodiments, variation of P_{out,IM3} with respect to V_{g} may comprise one or more local minimums within a given V_{g} range. For example, P_{out,IM3}−V_{g} curve 504 includes three local minimums at V_{go1}, V_{go1}, V_{go3} and three respective dips 506a, 506b, 506c, indicating three V_{g} intervals around V_{go1}, V_{go2} and V_{go3}. In the example shown in FIG. 5, V_{go1}≈0.4 volts, V_{go2}≈0.58, V_{go3}≈0.68 volts, and when V_{g} is equal or sufficiently close to V_{go1}, V_{go2}, or V_{go3}, P_{out,IM3} remains below-60 dBm. In some cases, a single dip may comprise two or more local minimums. In some implementations, V_{g} of a transistor may be biased near one of the local minimums of P_{out,IM3} to reduce P_{out,IM3} and improve the linearity of the amplification process. In some examples, V_{g} of a transistor may be biased at a V_{go} that provides larger linear gain and results in generation of larger level of P_{out,f}. For example, with reference to FIG. 5, V_{g} may be preferably biased at or near V_{go3}. As such to reduce the distortion of an amplifier circuit it can be desirable to design the amplifier circuit whose P_{out,IM3}−V_{g} curves for Pins within an operational Pᵢₙ range comprises very small local minimum.

In some cases, a 3 dB width of a dip in the P_{out,IM3}−V_{g} curve 504 may be defined as a range of V_{g} around V_{go} within which P_{out,IM3} is lower than an upper limit that is 3 dB larger than the corresponding local minimum. In some implementations, for given values of Pᵢₙ, V_{d}, frequency of Sᵢₙ, and other parameters of the amplifier circuit 400 external with respect to the FET 404, the 3 dB widths and the V_{go}'s may vary when an internal or intrinsic parameter of the FET 404 changes. In various embodiments, characteristics of the P_{out,IM3}−V_{g} curve 504 may depend on the nonlinear characteristics of the FET 404, particularly on gₘ₃ that may control the local minimums, e.g., widths, locations (V_{go}'s), and P_{out,IM3} at each V_{go}. In some examples, gₘ₃ may be controlled by the structure and material composition of the FET 404 (e.g., geometry, position and doping concentration of the source, gate, drain regions among other parameters).

In some examples, when a plurality of transistors are fabricated based on a common transistor design (e.g., structural and material characteristics), and are intended to have identical performance, e.g., identical gₘ's and gₘ₃'s, at least one of two transistors of the plurality of the transistors may have a different gₘ₃'s. As such, if the first and second amplifier circuits use a first FET and a second FET of these two FETs, but are otherwise identical, first and second P_{out,IM3}−V_{g} curves generated by the first and second amplifier circuits in response to a common Sᵢₙ, respectively, can be different. For example, the dip 506c near V_{go}=0.7 in the first P_{out,IM3}−V_{g} curve of the first amplifier circuit may be shifted relative to the second P_{out,IM3}−V_{g} curve of the second amplifier circuit for the same input signal. In some cases, a plurality of transistors may be co-fabricated on different locations on a common wafer based on a common transistor layout/design that is identical for different transistors of the plurality of the transistors. In some such cases, a slight difference between the substrate properties (e.g., distribution of defects over a wafer) and variation of local fabrication parameters, two transistors fabricated on different locations of the wafer may have different performances (e.g., different values of gₘ, gₘ₃, or pinch-off voltage).

In some applications, multiple copies of an amplifier circuit may be fabricated using multiple transistors having the same design such that different copies of the amplifier circuit and the corresponding bias voltages are substantially identical. In such applications, at least two copies of the amplifier circuits may generate different levels of P_{out,IM3} in response to receiving a common Sᵢₙ due to a difference between gₘ₃'s of the transistor used in each of the amplifier circuits. In some embodiments, when V_{g} of the amplifier circuit is designed to be near a local minimum of the P_{out,IM3}−V_{g} curve (V_{g}≈V_{go}), a shift of V_{go} the corresponding dip, e.g., due to variations of gₘ₃, can translate to a change in the P_{out,IM3}. In some cases, for a given shift of the local minimum the resulting P_{out,IM3} variation can depend on a curvature of P_{out,IM3}−V_{g} curve at or near the local minimum and the 3 dB width of the corresponding dip. As such, to reduce the performance variation across multiple copies of an amplifier circuit it can be desirable to design the amplifier circuit such that its P_{out,IM3}−V_{g} curves, for Pᵢₙ's within an operational Pᵢₙ range, comprise a small local minimum, small variations near the local minimum, and a corresponding dip having large 3 dB width.

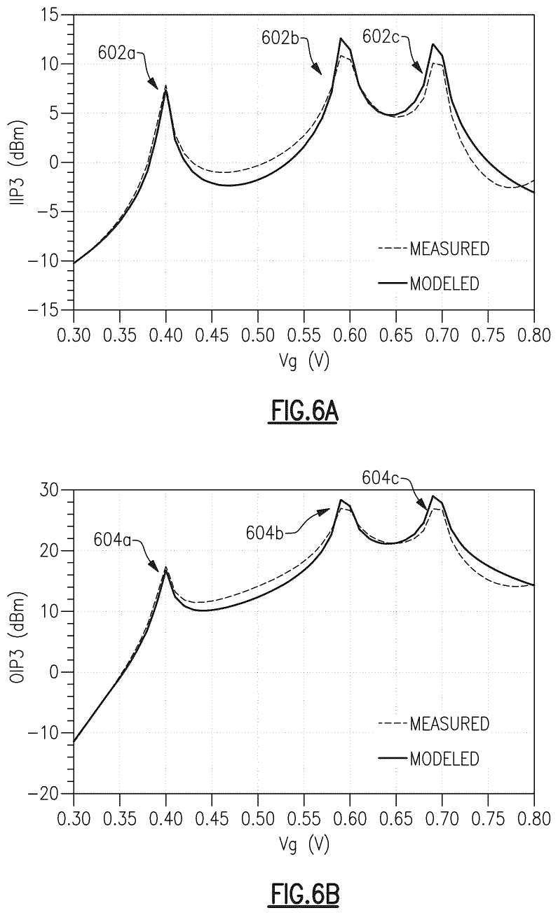

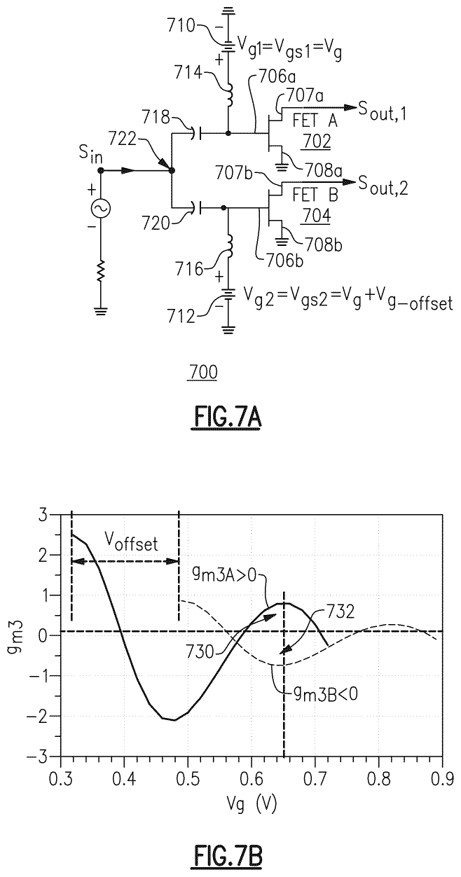

FIGS. 6A-6B show measured and calculated variation of input and output third order intercept points, IIP3 and OIP3, with respect to gate voltage (V_{g}) for the amplifier circuit 400 based on the same parameters used to obtain P_{out,f}−V_{g} curve 502 and P_{out,IM3}−V_{g} curve 504 shown in FIG. 5. The peaks 602a, 602b, 602c and the respective local maximums correspond to the dips 506a, 506b, 506c, and the respective local minimums.

Various embodiments of the amplifier circuits disclosed and described below are configured to reduce the RF power of nonlinear frequency components (e.g., P_{out,IM3}) in the spectrum of an amplified RF output signal, e.g., compared to some of the existing amplifier circuits.

In some embodiments, the disclosed amplifier circuits may comprise two or more transistors contributing to generation of an amplified RF output signal and configured to reduce RF power of a nonlinear frequency component (e.g., a third order component such as an intermodulation product) compared to RF power of the respective nonlinear frequency component generated by a single-transistor amplifier circuit (e.g., the amplifier circuit 400), for the same level of RF input RF power (Pᵢₙ). In some embodiments, the two or more transistors (e.g., two or more FETs) may have the same design and structure, and/or the same, substantially the same, or about the same values of gₘ, gₘ₃, pinch-off voltage (Vₚ), or other performance parameters, however they may be biased differently.

Dual Transistor Amplifiers with Reduced Third Nonlinearity

In some embodiments, an amplifier circuit may comprise two or more transistors (e.g., two FETs) configured to receive an RF input signal (Sᵢₙ) from a single input port, separately amplify the RF input signals, and provide the resulting amplified signals (also referred to intermediate amplified signals) to a single output port to generate an amplified output signal (also referred to as combined output signal). In various implementations, the combined output signal can be a sum, or a weighted sum, or a different combination of the individual amplified signals. In some embodiments, the two or more transistors may be configured such that the magnitude of gₘ₃ of the amplifier circuit is smaller than those of the individual contributing transistors at least for one bias setting of the amplifier circuit. In some cases, the bias setting of the amplifier circuit may comprise magnitude and polarities of bias voltages applied to different nodes in the amplifier circuit. For example, two transistors may be biased such that at least for one bias setting, gₘ₃ of the first transistor is positive and the gₘ₃ of the second transistor is negative such that the magnitude of the gₘ₃ of the amplifier circuit becomes smaller than the gₘ₃'s of the individual transistors at the at least one bias setting. In some cases, gₘ₃ of the amplifier may be defined as the ratio between a small variation of an amplified current output from the output port and a small variation of an input voltage provided to the input port, where the small variation of an amplified current is caused by the small variation of the input voltage.

In some embodiments, at least one of the terminals of a first transistor of the amplifier circuit, may be biased at different voltages compared to the respective terminal of a second transistor. For example, the gate terminals of the two or more transistors may be biased at different voltages relative to the respective source terminals. As another example, the drain terminals of the two or more transistors may be biased at different voltages relative to the respective source terminals. In some such examples, at least one of the terminals of the first transistor and the respective terminal of the second transistor may be biased at substantially same voltage. In some embodiments, the two transistors that are biased differently may have the same design and structure, and/or the same, substantially the same, or about the same values of gₘ, gₘ₃, pinch-off voltage (Vₚ), or other performance parameters, however they may be biased differently.

In various embodiments, an amplifier circuit may comprise two substantially identical transistors that are biased differently, two different transistors that are biased similarly, or two different transistors that are biased differently.

For example, in some embodiments, an amplifier circuit may comprise two transistors having different designs and structures, or different gₘ, gₘ₃, pinch-off voltage (Vₚ), or different values of other performance parameters. In such an embodiment, the two transistors may be selected, connected and biased such that the magnitude of gₘ₃ of the amplifier circuit is smaller than those of the individual contributing transistors at least for one bias setting of the amplifier.

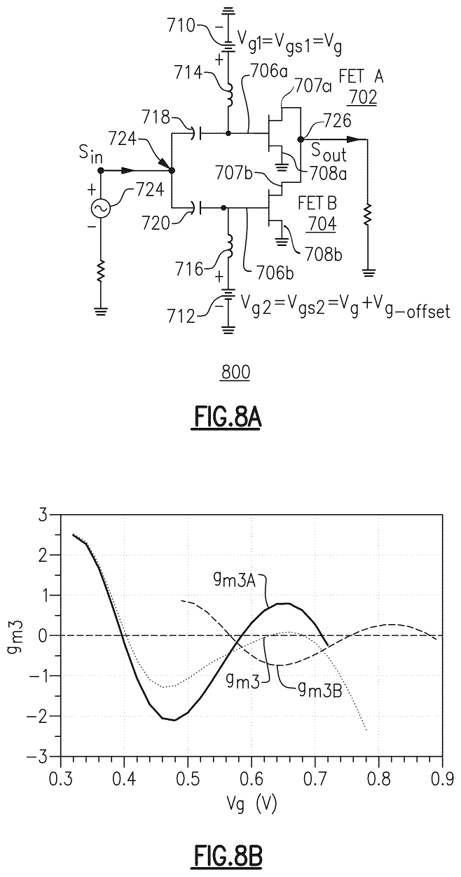

FIG. 7A is a circuit diagram of two commonly fed amplifier circuits 700 each including an FETs (e.g., a JFET) and configured such that the gₘ₃'s of the two amplifiers (or the two transistors) have opposite signs and close or about the same magnitudes at least for a range of bias settings. The two amplifier circuits are fed by a common input signal (Sᵢₙ) received via a common node or input port 722 and each output a separate amplified signal (referred to as intermediate amplified signal). A first amplifier circuit uses a first FET 702 to amplify Sᵢₙ and output a first RF output signal (a first intermediate amplified signal, S_{out,1}) and a second amplifier circuit uses a second FET 704 to amplify Sᵢₙ and output a second RF output signal (a second intermediate amplified signal, S_{out,2}). In some embodiments, each of the two amplifier circuits may comprise one or more features described above with respect to the amplifier circuit 400.

In some embodiments, the first gate terminal 706a (also referred to as gate 706a) of the first FET 702 can be electrically coupled to the input port 722. In some implementations, the first gate 706a may be biased at a first gate bias voltage (V_{gs1}) with respect to a first source terminal 708a of the FET 702. In some examples, the first gate 706a can be electrically connected to a first gate bias voltage source 710 configured to bias the first gate 706a at V_{gs1}. In some examples, the first gate 706a may be electrically connected to the first gate voltage source 710 through a first RF choke 714. In some examples, the first gate 706a can be capacitively coupled to the input port 722 through a first coupling capacitor 718. The first source terminal 708a (also referred to as first source 708a) of the FET 702 can be connected to a reference node configured to maintain a potential of the first source 708a at a first reference potential. In some examples, the first reference potential can be ground potential. In some implementations, the first FET 702 may output S_{out,1} via a first drain terminal 707a (also referred to as the first drain 707a). In some examples, the first drain 707a can be biased at a first drain bias voltage (V_{ds1}) with respect to the first source 708a.

In some embodiments, the second gate terminal 706b (also referred to as gate 706b) of the second FET 704 can be electrically coupled to the input port 722. In some implementations, the second gate 706b may be biased at a second gate bias voltage (V_{gs2}) with respect to a second source terminal 708b of the FET 704. In some examples, the second gate 706b can be electrically connected to a second gate bias voltage source 712 configured to bias the second gate 706b at a second gate bias voltage (V_{gs2}). In some examples, the second gate 706b may be electrically connected to the second gate voltage source 712 through a second RF choke 716. In some examples, second gate 706b can be capacitively coupled to the input port 722 through a second coupling capacitor 720. The second source terminal 708b (also referred to as second source 708b) of the FET 704 can be connected to a second reference node configured to maintain a potential of the second source 708b at a second reference potential. In some examples, the second reference potential can be a ground potential. In some implementations, the second FET 704 may output S_{out,2} via a second drain terminal 707b (also referred to as the second drain 707b). In some examples, the second drain 707b can be biased at a second drain bias voltage (V_{ds2}) with respect to the second source 708b.

In some embodiments the second gate bias voltage (V_{gs2}) can be offset with respect to the first gate bias voltage (V_{gs1}) by an offset voltage (V_{offset}).

In some implementations, the first and second reference nodes can be the same node or can be electrically connected. In some implementations, the first and second reference nodes may be connected to ground potential. In some such implementations, the first and second gate bias voltages are voltages applied with respect to ground potential and represented by V_{g1} and V_{g2}. In some embodiments, the second gate bias voltage (V_{g2}) can be offset with respect to the first gate bias voltage (V_{g1}) by an offset voltage (V_{offset}).

In some embodiments, the V_{offset} may be adjusted such that for at least one value of V_{g1} (and the respective value of V_{g2}=V_{g1}+V_{offset}), a first third order transconductance (g_{m3,A}) of the first FET 702 a second transconductance (g_{m3,B}) of the second FET 704, have opposite signs and a difference between the magnitude (absolute value) of g_{m3,A} and g_{m3,B} is less than both g_{m3,A} and g_{m3,B}. In some embodiments, the V_{offset} may be adjusted such that for at least one value of V_{g1} (and the respective value of V_{g}2=V_{g}1+V_{offset}), the second derivatives of g_{m3,A} and g_{m3,B} with respect to V_{g1} have opposite signs (e.g., d²g_{m3,A}/dV_{g1}²>0 and d²g_{m3,B}/dV_{g1}²>0).

FIG. 7B shows calculated variation of g_{m3,A} and g_{m3,B} when Vg (=V_{g1}) is varied from 0.3 volts to 0.9 volts and V_{ds}1=V_{ds2} is constant. As shown in FIG. 7B, between V_{g}=0.6 volts and V_{g}=0.7 volts, g_{m3,A} is positive, g_{m3,B} is negative and the difference between the magnitude of g_{m3,A} and magnitude of g_{m3,B} is less than both g_{m3,A} and g_{m3,B}. In this examples, in addition to g_{m3,A} and g_{m3,B}, d²g_{m3,A}/dV_{g1}² and d²g_{m3,B}/dV_{g1}² also have opposite signs from V_{g}=0.6 volts and V_{g}=0.7 volts (as indicated by the opposite concavities of the respective portions 730, 732 of the g_{m3,A}−V_{g} and g_{m3,B}−V_{g} curves).

The behavior and characteristics of g_{m3,A}−V_{g} and g_{m3,B}−V_{g} curves in FIG. 7B indicate that when the first and second drains 707a, 707b, are electrically connected to common node or a combiner to provide a single output port signal, the third order transconductance (gₘ₃) of the resulting amplifier circuit, defined based on the voltage provided to input port 722 and the current output by the output port can be smaller than g_{m3,A} and gₘ₃. In some embodiments, the combined output signal (Sₒᵤₜ), output by the single output port can be a sum or weighted sum of the first and second RF output signals S_{out,1}, S_{out,2} (also referred to as the first and second intermediate amplified signals) and the RF power of a third order nonlinear frequency component (e.g., a third harmonic or an intermodulation product) in the spectrum of Sₒᵤₜ can be smaller than those of the S_{out,1} and S_{out,2}.

FIG. 8A is a schematic diagram of a dual-transistor amplifier circuit 800 with reduced distortion (e.g., third order nonlinear distortion). In some embodiments, the dual-transistor amplifier circuit 800 may comprise one or more features described above with respect to the commonly fed amplifier circuits 700. In one embodiment, the dual-transistor amplifier circuit 800 can include the commonly fed amplifier circuits 700 and an output port electrically coupled to the first drain 707a and second drain 707b, and configured to output a combined RF output signal comprising a combination of the RF output signals S_{out,1} and S_{out,2} generated by the first and second FETs 702, 704.

In some embodiments, the dual-transistor amplifier circuit 800 comprises an input port 724 configured to receive an input signal (Sin), a first FET 702 configured to receive Sᵢₙ from the input port 724, a second FET 704 configured to receive Sᵢₙ from the input port 724, and an output port configured to receive a first amplified signal from the FET 702 and a second amplified signal from the second FET and output a combined output signal comprising a combination of the first and second amplified signals. In some embodiments, the first and second FETs 702, 704, can be substantially identical FETs that are differently biased to reduce an overall gₘ₃ of the amplifier circuit 800 compared to the individual gₘ₃'s of each of the FETs. In some implementations, the first gate 706a of the first FET 702 and the second gate 706b of the second FET 704 are electrically coupled to the input port 724 and the first drain 707a of the first FET 702 and the second drain 707b of the second FET 704 are electrically coupled to the output port 726. In some implementations, the first gate 706a of the first FET 702 and the second gate 706b of the second FET 704 are electrically coupled to the input port 724 by the first and second capacitors 718, 720, respectively, and the first drain 707a of the first FET 702 and the second drain 707b of the second FET 704 are electrically connected a common node 726 serving as the output port 726. However, the embodiments are not so limited and various implementations the first drain 707a of the first FET 702 and the second drain 707b of the second FET 704 can be electrically coupled to the output port 726 by other means (e.g., by two capacitors, by a combiner, or the like). In some embodiments, the first and second sources 708a, 708b can be electrically connected to a common reference potential (e.g., ground potential).

In some embodiments, the first gate 706a of the first FET 702 may be biased with respect to the first source 708a of the first FET at a first gate-source bias voltage (Vgs1) and the second gate 706b of the second FET 704 may be biased with respect to the second source 708b of the second FET at a second gate-source bias voltage (Vgs2) such that V_{gs1}−V_{gs2}=V_{offset}, where V_{offset} is selected to provide a specified relation between the first transconductance (g_{m3A}) of the first FET 702 and the second transconductance (g_{m3B}) of the second FET 704. In some embodiments, V_{offset} may be configured such that variations of g_{m3A} and g_{m3B} with respect to V_{gs} comprise one or more features described above with respect to FIG. 7B. In some embodiments, V_{offset} can be configured such that for a given RF input power (Pᵢₙ), the P_{out-IM3} generated by the amplifier circuit 800 can be smaller than that of a single-transistor amplifier circuit (e.g., the amplifier circuit 400) implemented based on the same transistors used in the dual-transistor amplifier circuit 800. For example, P_{out-IM3}−V_{g} curve for the dual-transistor amplifier circuit 800 may comprise a dip that has a smaller local minimum and a larger 3 dB width, compared to a respective dip in the P_{out-IM3}−V_{g} curve for the single-transistor amplifier circuit 400, at near a V_{go}.

In the example shown in FIG. 8A, the first and second sources 708a, 708b, are electrically connected directly connected to ground potential (V_{gs1}=V_{g1} and V_{gs2}=V_{g2}) and V_{offset} (=V_{g2}−V_{g1}), is configured such that that variations of g_{m3A} and g_{m3B} are identical to the respective variation shown in FIG. 7B. Moreover, the first and second drains 707a, 707b are electrically connected to the output port 726, and the first and second drains 707a, 707b are biased at a common voltage (V_{d}) with respect to the grounded first and second sources 708a, 708b. The first and second gate bias voltages V_{g1} and V_{g2} are provided by the first and second voltage sources 710, 712 connected between the first and second gates 706a, 706b, and the ground potential via the first and second RF chokes 714, 716, respectively.

In some embodiments, the output port of a dual-transistor amplifier circuit similar to the amplifier circuit 800 may be electrically coupled to the source terminals of the corresponding FET (e.g., first and second sources 708a, 708b), instead of the drain terminals.

FIG. 8B shows calculated variation of third order transconductance (gₘ₃) provided by the amplifier circuit 800 with respect to gate voltage (V_{g1}=V_{g}) of the first FET 702. Here, the input RF signal (Sᵢₙ) is a single tone signal having a frequency of 0.5 GHZ, the RF power of the input signal (Pᵢₙ) is about-20 dBm, and V_{g} is scanned from 0.3 volts to 0.8 volts, V_{d}=3 volts. The first and second third order transconductances (g_{m3A}, g_{m3B}) provided by the corresponding single-transistor amplifier circuits are also shown for comparison. As shown in the plot, the magnitude of gₘ₃ is smaller compared to the magnitudes of g_{m3A} and g_{m3B} when V_{g} is less than 0.7 volts. More specifically, when V_{g} is between 0.6 volts and 0.7 volts, the magnitude of gₘ₃ is less than 0.5 volts. As such when V_{g} is between 0.6 volts and 0.7, the third order distortion of the dual-transistor amplifier circuit 800 can be smaller than those of the individual single amplifier circuits 700.

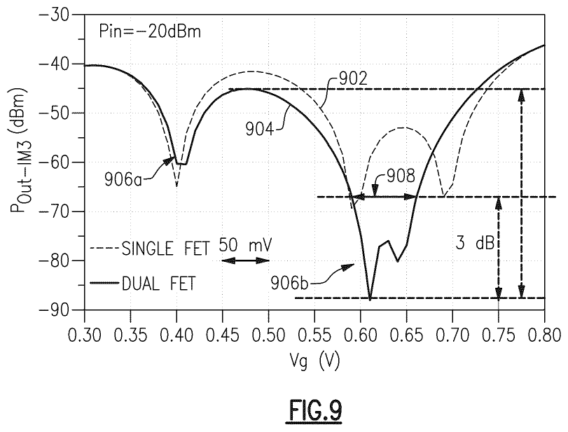

FIG. 9 shows calculated variation of third order intermodulation RF output power (P_{out-IM3}) with respect to gate voltage (V_{g}) at a fixed drain-source voltage (V_{d}), for the dual-transistor amplifier circuit 800 and one of the single-transistor amplifier circuits of the commonly fed amplifier circuits 700, where all FETs are identical. Here, the input RF signal (Sᵢₙ) is a single tone signal having a frequency of 0.5 GHZ, the RF power of the input signal (Pᵢₙ) is about-20 dBm, and V_{g} is scanned from 0.3 volts to 0.8 volts, and V_{d}=3 V. The P_{out-IM3}−V_{g} curve 902 of the single-transistor amplifier circuit comprises three local minimums and three corresponding dips, and the P_{out-IM3}−V_{g} curve 904 of the dual-transistor amplifier circuit 800 comprises a first dip 906a close to the first dip of the P_{out-IM3}−V_{g} curve 902, and a second dip 906b spanning the V_{g} range that includes the second and third dips of the P_{out-IM3}−V_{g} curve 902. In some examples, the 3 dB width 908 of the second dip 906b of the P_{out-IM3}−V_{g} curve 904 can be larger than the 3 dB width of any of the dips in P_{out-IM3}−V_{g} curve 902. In some cases, such as the example shown in FIG. 9, the second dip 906b of the P_{out-IM3}−V_{g} curve 904 may comprise two local minimums each being smaller than the local minimums of the P_{out-IM3}−V_{g} curve 902.

As such when V_{g} of the dual-transistor amplifier circuit 800 is fixed to be within the 3 dB width of the second dip 906b of the P_{out-IM3}−V_{g} curve 904, P_{out-IM3} of the dual-transistor amplifier circuit 800 can be smaller than the P_{out-IM3} of a single-transistor amplifier circuit that uses the same FET as those used in the dual-transistor amplifier circuit 800. Moreover, given the large 3 dB width of the second dip 906b, the performance of the dual-transistor amplifier circuit 800 (e.g., with respect to third order nonlinearity) can be more robust against unexpected variation of V_{g} (over time or for different copies of the dual-transistor amplifier circuit 800), compared to a corresponding single-transistor device. In some examples, such as the examples shown in FIG. 9, a local minimum of the P_{out-IM3}−V_{g} curve 904 may comprise an absolute minimum within an operational range for Ve. In some such examples, V_{g} may be adjusted to be near or substantially equal to the absolute minimum.

In various applications, V_{g} may be adjusted to generate a smaller level of P_{out-IM3} and/or provide robust linear (less distorted) performance against V_{g} variations. In some implementations, V_{g} may be selected taking into account a tradeoff between robustness against V_{g} variations and a lower level of P_{out-IM3}.

In some embodiments, when Pᵢₙ is smaller than or equal to −20 dBm, a local minimum of the P_{out-IM3}−V_{g} curve 904 can be smaller than −70 dBm, than −80 dBm, smaller than −90 dBm, or smaller values.

In some embodiments, a 3 dB width of a dip in the P_{out-IM3}−V_{g} curve 904 can be larger than 30 millivolts, larger than 50 millivolts, larger than 60 millivolts, larger than 70 millivolts larger than 80 millivolts, or larger values.

In some embodiments, when Pin is smaller than or equal to −20 dBm, the amplitude of a third order intermodulation frequency component of in the RF output signal generated by the dual-transistor amplifier circuit 800 can be larger than the amplitude of the fundamental frequency component of the RF output signal by larger than 5 dB, larger than 7 dB, larger than 10 dB, larger than 15 dB, larger than 20 dB, or larger values.

In some implementations, the V_{offset} may be constant during operation of the dual-transistor amplifier circuit 800. In some implementations, the V_{offset} may be dynamically adjusted during an operation period of the dual-transistor amplifier circuit 800 to maintain a desired low distortion performance (e.g., low P_{out-IM3}). For example, an RF system (e.g., a wireless system) comprising the dual-transistor amplifier circuit 800 may further comprise an electronic controller (or processor) configure to control (e.g., feedback control) V_{g} to maintain P_{out-IM3} (or another nonlinear frequency product) below a threshold value.

In some embodiments, such as the example shown in FIG. 8A, the combined output signal (Sₒᵤₜ) can be a sum of the first and second amplified signals (also referred to as first and second intermediate amplified signals) generated by the first and second FETs 702, 704. In some embodiments, the combined output signal (Sₒᵤₜ) can be a weighted sum of the first and second amplified signals generated by the first and second FETs 702, 704. For example, first and second amplified signals generated by the first and second FETs 702, 704 can be provided to a combiner that reduces the amplitude of one of the amplified signals before combining it (e.g., adding it) to the other signal such that the resulting gₘ₃ becomes smaller compared to the case where the two amplified signals are directly added.

In some embodiments, the first and second FETs 702, 704 may be designed or selected to be different. For examples, at least one parameter (e.g., gₘ, gₘ₃, Vₚ, or the like) of the first FET 702 can be different from the respective parameter of the second FET 704, to make the performance of the dual-transistor amplifier circuit 800 more linear (e.g., by reducing reduce gₘ₃). In some cases, V_{offset} and parameters of the first and second FETs of a dual-transistor amplifier circuit may be selected to provide a lower value of gₘ₃ compared to a dual-transistor amplifier circuit having identical FETs (e.g., FETs designed to be identical).

In various implementations, the first and second FETs 702, 704 can be JFETs.

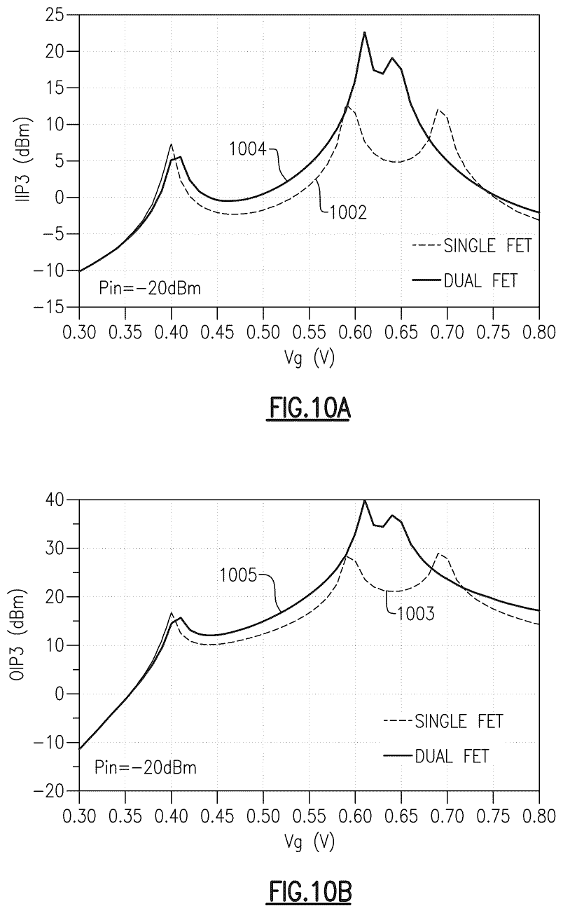

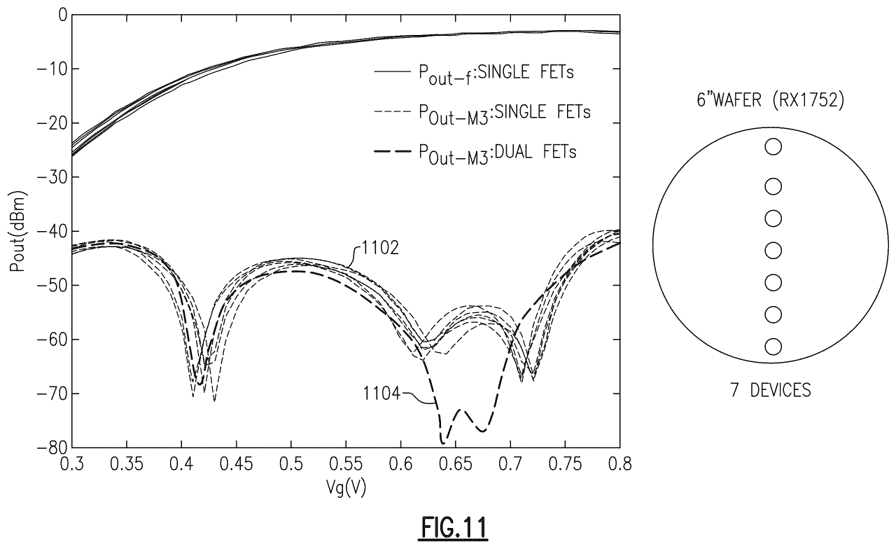

FIGS. 10A-10B show calculated variation of input and output third order intercept points, IIP3 and OIP3, with respect to gate voltage (V_{g}) at a fixed drain-source voltage (V_{d}), for the dual-transistor amplifier circuit 800 and one of the single-transistor amplifier circuits shown in FIG. 7A corresponding to the P_{out-IM3}−V_{g} curves 902, 904 (e.g., based on the same parameters used to obtain P_{out-IM3}−V_{g} curves 902, 904 shown in FIG. 9). The peaks and the respective local maximums of the IIP3−V_{g} curve 1002 correspond to the dips and the respective local minimums of the P_{out-IM3}−V_{g} curve 902 and the peaks and the respective local maximums of the IIP3−V_{g} curve 1004 correspond to the dips and the respective local minimums of the P_{out-IM3}−V_{g} curve 904.

As described above, in some cases, a parameter of one or more transistors of a plurality of transistors that are designed and fabricated to be substantially identical, can be different from those of the other transistors of the plurality of transistors. For example, a parameter (e.g., different values of gm, gm3, or pinch-off voltage) of some of a plurality of transistors that are co-fabricated on different wafters or on different regions of a common wafer and based on a common transistor layout/design, can be different from those of the other transistors of the plurality of transistors due to a difference between the substrate properties (e.g., distribution of defects over a wafer or in two different wafers), variation of local fabrication parameters. As such, multiple copies of an amplifier circuit fabricated using transistors having the same design and similarly biased, may generate different levels of P_{out,IM3} in response to receiving a common Sin due to a difference between gₘ₃'s of the transistors used in each of the amplifier circuits.

FIG. 11 shows calculated variation of fundamental output RF power and third order intermodulation RF power (P_{out-IM3}) with respect to gate voltage (V_{g}), at a fixed drain-source voltage (V_{ds}), measured for seven copies of a single-transistor amplifier circuit (e.g., single-transistor amplifier circuit 400 or one of the transistor amplifier circuits 700), where each amplifier circuit uses a different one of seven FETs co-fabricated on a common wafer. An estimated calculated variation of third order intermodulation RF power (P_{out-IM3}) with respect to gate voltage (V_{g}), is also shown for the dual-transistor amplifier circuit 800 for comparison (dashed curve). In the example shown, the local minimums and corresponding dips in the P_{out-IM3}−V_{g} curves 1102 for different single-transistor amplifier circuits that use different ones of the seven co-fabricated FET having identical designs, are shifted with respect to each other. In some examples, the difference between P_{out-IM3} V_{g} curves 1104 measured for different amplifier circuits may be associated with variation of a parameter over the seven co-fabricated FET. For example, one or more of the seven transistors may have different pinch-off voltages (Vₚ's). It may be reasonable to expect a similar distribution for P_{out-IM3}−V_{g} curves for multiple copies of the double-transistor amplifier circuit 800 each using a pair of transistors having different Vₚ's. Advantageously, when V_{g} is biases near or at a local minimum within the second dip of P_{out-IM3}−V_{g} curves 1104, variation of Vₚ's in different transistors may result in a smaller variation of P_{out-IM3} over multiple copies of the dual-transistor amplifier circuits compared to variation of P_{out-IM3} over multiple copies of the single-transistor amplifier circuits. As such, in some cases, a yield of dual-transistor amplifier circuits can be greater than that of the single-transistor amplifier for a given tolerance with respect to P_{out-IM3} variation. Additionally, for a given level of output power, the overall performance of dual-transistor amplifier circuits can be better than the single-transistor circuits because P_{out-IM3} generated by a dual-transistor amplifier circuit can more than 10 dB be better than that of the single-transistor (as indicated by a smaller local minimum of the second dip in P_{out-IM3}−V_{g} curve 1104 compared to the third local minimum of the P_{out-IM3}−V_{g} curve 1102).

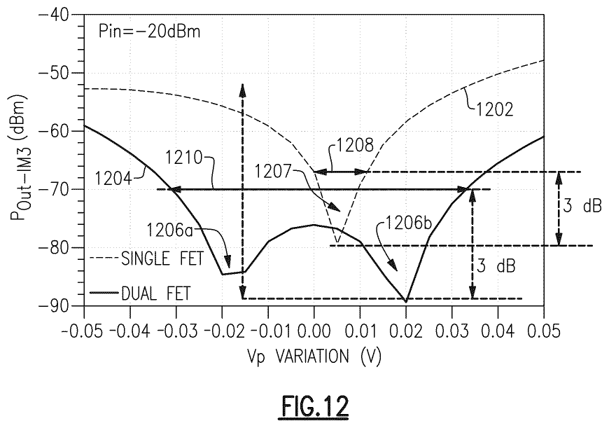

FIG. 12 shows calculated variation of third order intermodulation RF power (P_{out-IM3}) with respect to pinch-off voltage (Vₚ) of the FET(s), for the dual-transistor amplifier circuit 800 and one of the single-transistor amplifier circuits 700, when V_{d} and V_{g} are fixed. In this example, the input RF signal (Sᵢₙ) is a single tone signal having a frequency of 0.5 GHZ, the RF power of the input signal (Pᵢₙ) is about-20 dBm, and Vₚ is scanned from −0.05 volts to 0.05 volts, and V_{d}=3 volts. The P_{out-IM3}−Vₚ curve 1202 of the single-transistor amplifier circuit includes a dip having a 3 dB width of about 0.01 volts and local minimum of −80 dB near 0.005 volts. The P_{out-IM3}−Vₚ curve 1204 of the dual-transistor amplifier circuit includes a dip having a 3 dB width of about 0.065 volts and two local minimums of −84 dB, −90 dB near −0.02 volts and 0.02 volts, respectively. As such, the magnitude and variation of P_{out-IM3} generated by the dual-transistor amplifier circuit 800 is smaller than those of the a single-transistor amplifier circuit over a wide range of Vₚ's. For example, a change Vₚ from 0.005 volts to −0.01 volts result in 20 dB increase in P_{out-IM3} generated by a single-transistor amplifier circuit compared to less than 2 dB change in P_{out-IM3} generated by a dual-transistor amplifier circuit that uses FETs having characteristic identical to those of the FET used in the single-transistor amplifier circuit. As such performance of the dual-transistor amplifier circuit 800 can be more robust against Vₚ variations compared to a single-transistor amplifier circuit.

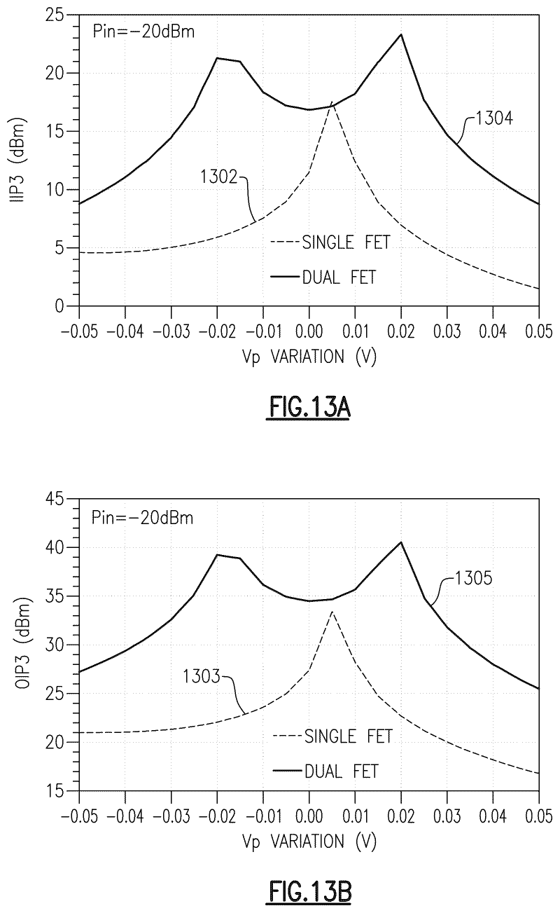

FIGS. 13A-13B show calculated variation of input and output third order intercept points, IIP3 and OIP3, with respect to pinch-off voltage (Vₚ) at a fixed V_{d} and V_{g}, for the dual-transistor amplifier circuit 800 and a single-transistor amplifier circuit corresponding to the P_{out-IM3}−Vₚ curves 1202, 1204 (e.g., based on the same parameters used to obtain P_{out-IM3}−Vₚ curves 1202, 1204 shown in FIG. 12). The peak and the respective local maximum of the IIP3−Vₚ curve 1302 correspond to the dip and the respective local minimum of the P_{out-IM3}−V_{g} curve 1202 and the peaks and the respective local maximums of the IIP3−Vₚ curve 1204 correspond to the dips and the respective local minimums of the P_{out-IM3}−Vₚ curve 1204.

In some embodiments, a dual-transistor amplifier circuit may be configured to have a reduced gₘ₃ compared to a single-transistor amplifier circuit, which uses a transistor identical to those used in the dual-transistor amplifier circuit, based on a bias setting different than that of the dual-transistor amplifier circuit 800. For example, in some embodiments, the gates of the two FETs (e.g., JFETs) used in the dual-transistor amplifier circuit may be biased at the same gate bias voltage (e.g., with respect to the respective source voltages) and an offset voltage V_{offset}−d between the drain voltage biases of the two FETs may be configured to provide a reduced gₘ₃.

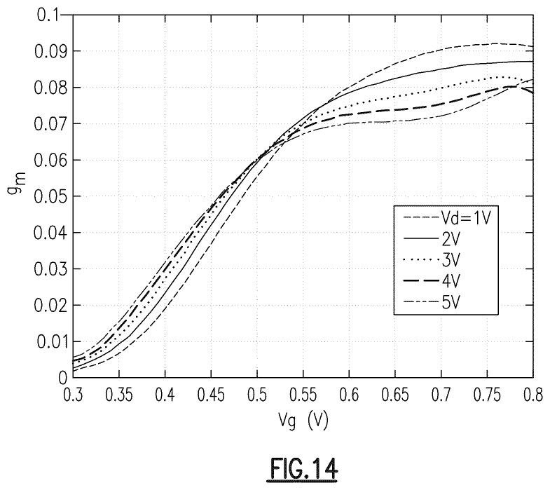

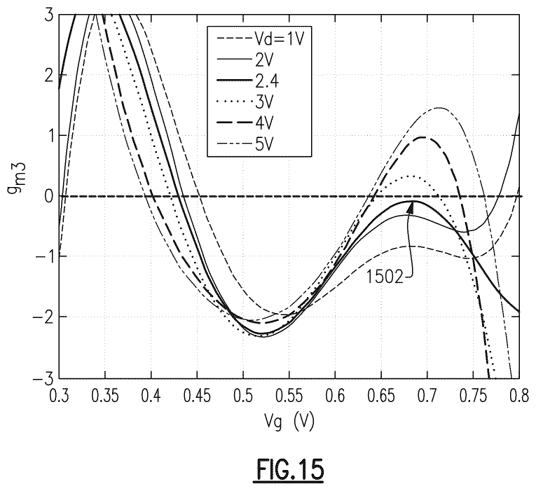

FIG. 14 shows measured variation of linear (or fundamental) transconductance (gₘ) provided by an FET or a single-transistor amplifier circuit, with respect to the gate voltage (V_{g}), for five different values of drain voltage (V_{d}) indicating that, in some cases, increasing V_{d} may suppress gₘ at larger values of V_{g} (e.g., >0.55 volts for the example shown) but may not cause significant change in the behavior of the gₘ−V_{g} curve. Here Pᵢₙ=−60 dBm and V_{g} is scanned from 0.3 volts to 0.8 volts for V_{d}=1, 2, 3, 4, and 5 volts.

FIG. 15 shows measured variation of third transconductance (gₘ₃) provided by the same FET or a single-transistor amplifier circuit used to generate the gₘ−V_{g} curve in FIG. 14, with respect to the gate voltage (V_{g}) and for the same six values of drain voltage (V_{d}). indicating that, in some cases, increasing V_{d} may change gₘ₃ from negative values to positive values for a certain range of V_{g} values (e.g., between 0.65 and 0.75 volts for the example shown) but may not cause significant change in the behavior of the gₘ−V_{g} curve. Here V_{g} is scanned from 0.3 volts to 0.8 volts for V_{d}=1, 2, 3, 2.4, 4, and 5 volts. Advantageously, the fact that adjusting V_{d} can change the gₘ₃ from a negative value to a positive value having close or substantially equal to the magnitude of the negative value, suggests that in some embodiments, by properly biasing the drains of pair of FETs in a dual-transistor amplifier circuit (e.g., connected between a common input port and a common output port similar to the amplifier circuit 800), the gₘ₃ of the dual-transistor amplifier circuit (with respect to the common input and output ports) can become smaller than the gₘ₃ of a corresponding single-transistor amplifier circuit implemented based on an FET substantially identical to the FET of the pair of FETs. In various embodiments, properly biasing the drains of pair of FETs may comprise one or both of adjusting/selecting one of the drain bias voltages and a drain bias voltage offset (V_{offset}−d) between the two drain bias voltages.

For example, with reference to the gₘ₃−V_{g} plot in FIG. 15, when V_{g}=0.7 values of gₘ₃ at V_{d}=1 volt and V_{d}=4 volts. As such, when two copies of the FET used to generate the measured values of gₘ₃ in FIG. 15 are combined in a dual-transistor amplifier circuit and are biased to have substantially the same gate bias voltage in the 0.65 to 0.74 range and different drain bias voltages at V_{d}=1 volt and V_{d}=4 volts, the gₘ₃ of the dual-transistor amplifier circuit can be very small.

In some embodiments, the gₘ₃ of a single-transistor amplifier circuit may be minimized for a given V_{g} range by adjusting Va. For example, with reference to the gₘ₃−V_{g} plot in FIG. 15, when V_{d}=2.4 volts gₘ₃ can be smaller than −0.3 volts for values of Ve between 0.65 and 0.7 volts. In some embodiments, by properly adjusting/selecting the drain bias voltages of FETs in a dual-transistor amplifier circuit, the gₘ₃ of dual-transistor amplifier circuit may become smaller than that of a single-transistor amplifier circuit implemented based on the same FETs. In some cases, the dual-transistor amplifier circuit may provide the smaller gₘ₃ over a broader V_{g} range.

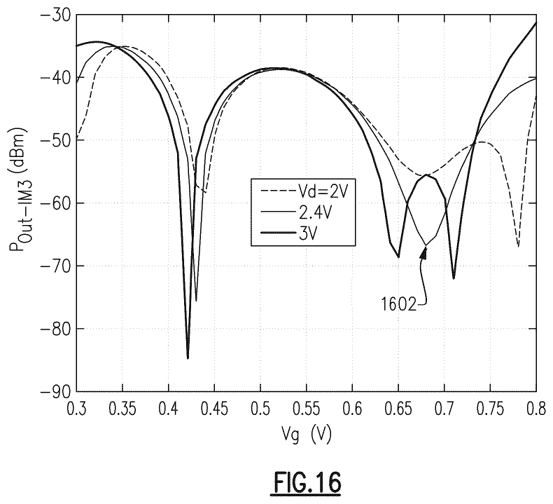

FIG. 16 shows calculated variation of third order intermodulation RF power (P_{out-IM3}) with respect to gate voltage (V_{g}) for a single-transistor amplifier circuit including the FET used to generate the measured values of gₘ₃ in FIG. 15, for three different values of drain voltage (V_{d}). Here V_{g} is scanned from 0.3 volts to 0.8 volts for V_{d}=2, 2.4, and 3 volts. The P_{out-IM3}−V_{g} curves at V_{d}=2 and 3 volts, each include three local minimums and the P_{out-IM3}−V_{g} curve 1602 associated with V_{d}=2.4 (the optimal V_{d} for reducing gₘ₃, according to FIG. 15) includes two local minimums. As described above with respect to FIG. 5 and as evident from FIG. 14, in some cases, V_{g} may be adjusted to be at or close to a local minimum occurring at larger values of V_{g} to increase the linear gain (gₘ) of the amplifier circuit. Moreover, operating at or near a dip in the P_{out-IM3}−V_{g} curve having a large 3 dB width may improve robustness of the linear performance of the amplifier circuit. As such, the single-transistor amplifier circuit associated with FIG. 16 may be biased at or near V_{g}=0.67 volts and V_{d}=2.4 for optimal performance with respect to linearity (e.g., low third order distortion) and higher gain.

As described above, in some cases, a dual-transistor amplifier with properly biased transistors may outperform a single-transistor amplifier circuit (e.g., an optimally biased single-transistor amplifier circuit), with respect to generation of low level third order nonlinear frequency products (e.g., low P_{out-IM3}).

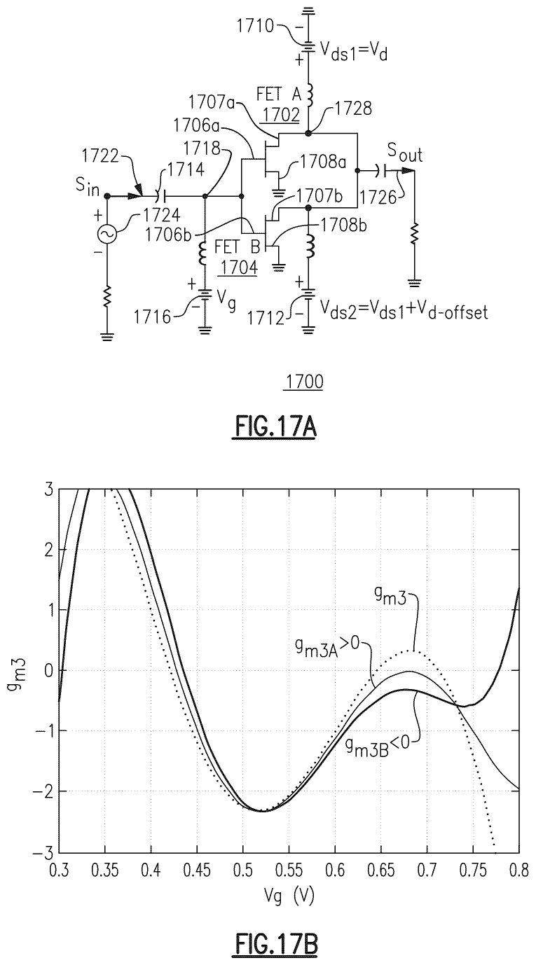

FIG. 17A is a circuit diagram of a dual-transistor amplifier circuit 1700 with reduced distortion having a pair FETs 1702, 1704 (e.g., JFETs) supplied with drain bias voltages adjusted and offset for providing a low magnitude of gₘ₃ at least for an optimal range of bias setting (e.g., an optimal range of V_{g}'s). In some embodiments, the pair of FETs 1702, 1704 are connected to a common input port 1722 such that each receive input signal (Sᵢₙ) and are configured such that their individual gₘ₃'s have opposite signs and close or about the same magnitudes for the optical range of bias settings.

In some embodiments the dual-transistor amplifier circuit 1700 may comprise a first FET 1702 and a second FET 1704 configured to amplify Sᵢₙ. In some examples, a first gate terminal 1706a (also referred to as first gate 1706a) of the first FET 1702 and a second gate terminal 1706b (also referred to as second gate 1706b) of the second FET 1704 can be electrically coupled to the input port 1722 (e.g., capacitively coupled to input port 1722 through a coupling capacitor 1714). In some embodiments, the first gate 1706a and the second gate 1706b can be biased at a common bias voltage V_{gs} (e.g., with respect to the respective source terminals). For example, the first gate 1706a and the second gate 1706b can be electrically connected (e.g., through an RF choke) to a gate voltage source 1716 configured to bias the first and second gates 1706a, 1706b at V_{gs}.

In some implementations, a first drain terminal 1707a (also referred to as first drain 1707a) of the first FET 1702 may be biased at a first drain bias voltage (V_{ds1}) with respect to a first source terminal 1708a of the first FET 1702. In some examples, the first drain 1707a can be electrically connected (e.g., through a RF choke) to a first drain bias voltage source 1710 configured to bias the first drain 1707a at V_{ds1}. The first source terminal 1708a (also referred to as first source 1708a) of the first FET 1702 can be connected to a reference node configured to maintain a potential of the first source 1708a at a first reference potential. In some examples, the first reference potential can be ground potential.

In some implementations, the second drain terminal 1707b (also referred to as second drain 1707b) of the second FET 1704 may be biased at a second drain bias voltage (V_{ds2}) with respect to a second source terminal 1708b of the second FET 1704. In some examples, the second drain 1707b can be electrically connected (e.g., through a RF choke) to a second drain bias voltage source 1712 configured to bias the second drain 1707b at V_{ds2}. The second source terminal 1708b (also referred to as second source 1708b) of the second FET 1704 can be connected to a reference node configured to maintain a potential of the second source 1708b at a second reference potential. In some examples, the second reference potential can be ground potential.

In some embodiments, the first FET 1702 and the second FET 1704 can be substantially identical FETs. In some embodiments, the first FET 1702 and the second FET 1704 can be substantially identical FETs by design. For example, a difference between parameters of the first and the second FETs 1702, 1704 may be limited to differences caused by fabrication uncertainties or unexpected variations in substate or substrates within which the first FET 1702 and the second FET 1704 are formed.

In various implementations, the first and second FETs 1702, 1704 can be JFETs.

In some embodiments, the first and second sources 1708a, 1708b and the gate voltage source 1716 can be electrically connected to a common reference potential (e.g., ground potential).

In some embodiments, the first drain 1707a of the first FET 702 and the second drain 1707b of the second FET 704 are capacitively coupled to a common output port 1726 via a capacitor. However, the embodiments are not so limited and various implementations the first drain 1707a of the first FET 1702 and the second drain 1707b of the second FET 1704 can be the coupled to the output port 1726 in other ways (e.g., directly connected, by a combiner, or the like).

In some embodiments, such as the example shown in FIG. 1700A, the combined output signal (Sₒᵤₜ) provided to the output port 1726 can be a sum of the first and second amplified signals generated by the first and second FETs 1702, 1704. In some embodiments, the combined output signal (Sₒᵤₜ) can be a weighted sum of the first and second amplified signals generated by the first and second FETs 1702, 1704. For example, first and second amplified signals generated by the first and second FETs 1702, 1704 can be provided to a combiner that reduces the amplitude of one of the amplified signals before combining it (e.g., adding it) to the other signal such that the resulting gₘ₃ becomes smaller compared to the case where the two amplified signals are directly added.

In some embodiments the second drain voltage (V_{ds2}) can be offset with respect to the first drain bias voltage (V_{ds1}) by an offset voltage (V_{offset}). In some implementations, the first and second reference nodes can be the same node or can be electrically connected. In some implementations, the first and second reference nodes may be connected to ground potential. In some such implementations, the first and second drain bias voltages are voltages applied with respect to ground potential and represented by V_{d1} and V_{d2}. In some embodiments the second drain bias voltage (V_{d2}) can be offset with respect to the first drain bias voltage (V_{d1}) by an offset voltage (V_{offset-d}=V_{d2}−V_{d2}).

In some embodiments, one or both V_{ds1} and V_{offset-d} may be adjusted, selected, or controlled such that for at least one value of Ve, or for a range of V_{g} values, a first third order transconductance (g_{m3,A}) of the first FET 1702 and a third order transconductance (g_{m3,B}) of the second FET 1704, have opposite signs and a difference between the magnitude (absolute value) of g_{m3,A} and g_{m3,B} is less than both g_{m3,A} and g_{m3,B}. In some embodiments, one or both V_{ds1} and V_{offset-d} may be adjusted such that for at least one value of Ve, or for a range of V_{g} values, the third order transconductance (gₘ₃) of the dual-transistor amplifier circuit 1700, with respect to input port 1722 and output port 1726, is smaller than the g_{m3,B} and g_{m3,A}.

In some implementations, V_{offset-d}, V_{g}, V_{ds1}, and V_{ds2} may be constant during operation of the dual-transistor amplifier circuit 1700. In some implementations, one or both V_{ds1} and V_{offset-d} may be dynamically adjusted during an operation period of the dual-transistor amplifier circuit 1700 to maintain a desired low distortion performance (e.g., a low level of P_{out-IM3}). For example, an RF system (e.g., a wireless system) comprising the dual-transistor amplifier circuit 1700 may further comprise an electronic controller (or processor) configure to control (e.g., feedback control) one or both V_{ds1} and V_{offset-d} to maintain P_{out-IM3} (or another nonlinear frequency product) below a threshold value.

FIG. 17B shows calculated variations of g_{m3,A}, g_{m3,B}, and gₘ₃ when V_{g} is varied from 0.3 volts to 0.9 volts, V_{ds}1=2 volts and V_{ds}2=3 volts (corresponding to V_{offset-d}=1 volt). As shown in FIG. 17B, between V2=0.6 volts and V_{g}=0.7 volts, g_{m3,A} is positive, g_{m3,B} is negative, and the difference between the magnitude of g_{m3,A} and magnitude of g_{m3,B} is less than both g_{m3,A} and g_{m3,B}. As shown in the plot, the magnitude of gₘ₃ is smaller compared to the magnitudes of g_{m3A} and g_{m3B} when V_{g} is between 0.65 volts and 0.7 volts. As such when V_{ds}1=2 volts, V_{offset-d}=1 volts and V_{g} is between 0.6 volts and 0.7, the third order distortion of the dual-transistor amplifier circuit 1700 can be smaller than a single-transistor amplifier circuit that uses the first or the second FETs 1702, 1704.

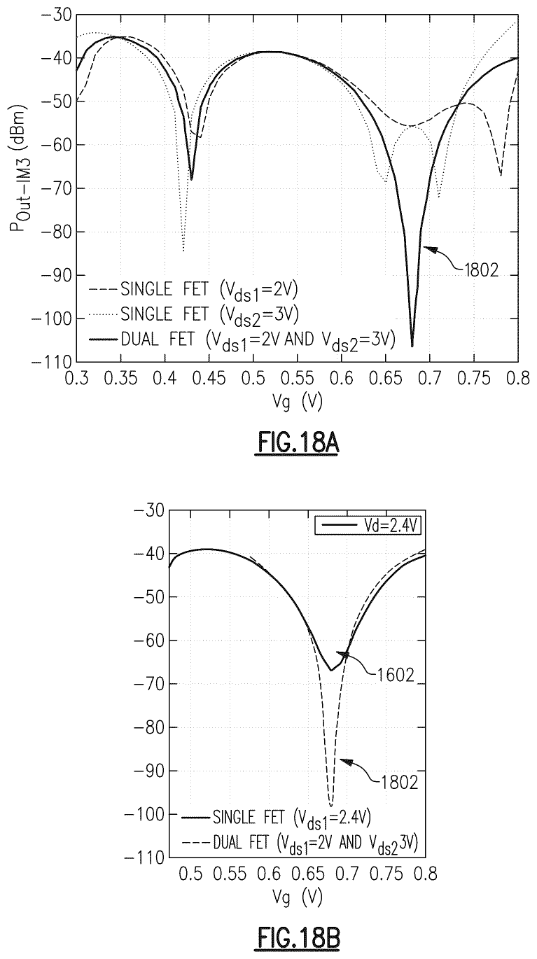

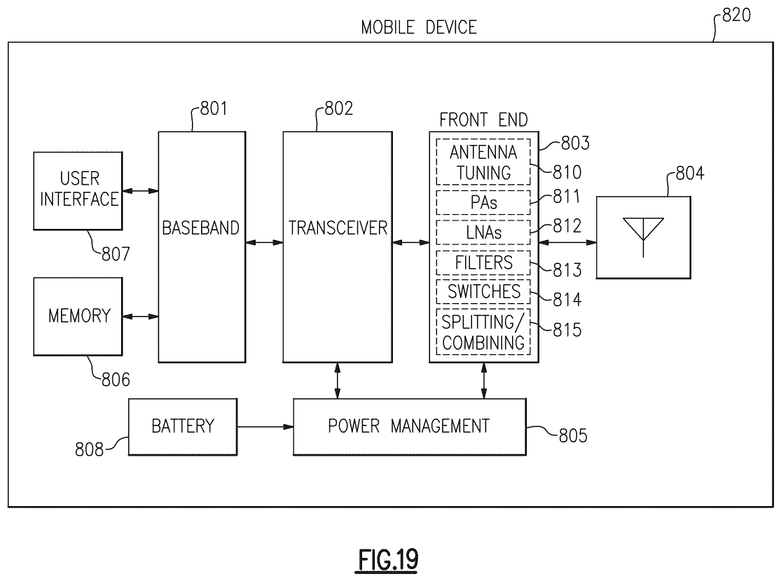

FIG. 18A shows calculated variation of third order intermodulation RF power (P_{out-IM3}) with respect to the common gate voltage (V_{g}), for the dual-transistor circuit 1700 when V_{d1}=2 and V_{d2}=3 (corresponding to V_{offset-d}=1 volt). Also shown, for comparison, are calculated variation of third order intermodulation RF powers (P_{out-IM3}) for a single-transistor amplifier circuit using the same FET as the first and second FETs 1702, 1704 when V_{d}=2 and V_{d}=3 (equivalent with the respective P_{out-IM3}−V_{g} curves in FIG. 16). As shown in FIG. 18A, the P_{out-IM3}−V_{g} curve 1802 for the dual-transistor amplifier circuit comprises a large dip (between V_{g}=0.62 volts and V_{g}=0.72 volts) having a minimum P_{out-IM3} (˜−108 dBm) that is smaller than the minimum P_{out-IM3}'s of any of the dips in the P_{out-IM3}−V_{g} curves of the corresponding single-transistor amplifiers, by more than 20 dB. As such commonly biasing the gates of the first and second FETs 1702, 1704, at 0.62 or between 0.65 and 0.7, and individually biasing first and second drains 1707a, 1707b, at V_{d1}=2 volts and V_{d2}=3 volts, significantly reduce P_{out-IM3} generated by the amplifier circuit 1700 compared to a corresponding single-transistor amplifier.

In various implementations, the optimal values of V_{g}, V_{d1}, and V_{d2} may be determined based on specific characteristics of the FETs used to form the dual-transistor amplifier circuit.

In some embodiments, when Pᵢₙ is smaller than or equal to −20 dBm, the amplitude of a third order intermodulation frequency component of in the RF output signal (the combined output signal, Sₒᵤₜ) generated by the dual-transistor circuit 1700 can be larger than the amplitude of the fundamental frequency component of the RF output signal by larger than 5 dB, larger than 7 dB, larger than 10 dB, larger than 15 dB, larger than 20 dB, or larger values.

FIG. 18B shows calculated variation of third order intermodulation RF power (IM3) for the dual-transistor amplifier circuit of FIG. 17A, when V_{d1}=2 and V_{d2}=3, and a corresponding single-transistor amplifier biased at an optimal drain voltage (V_{d}=2.4 volts in this example) when V_{g} is between 0.5 and 0.8 volts. The minimum of the P_{out-IM3}−V_{g} curve of dual-transistor amplifier is smaller than the minimum of the P_{out-IM3}−V_{g} curve of the optimally biased single-transistor amplifier by a factor larger than 35 dB.

FIG. 19 is a schematic diagram of one embodiment of a mobile device 820. The mobile device 820 includes a baseband system 801, a transceiver 802, a front-end system 803, antennas 804, a power management system 805, a memory 806, a user interface 807, and a battery 808. In some embodiments, the front-end system 803 may comprise a dual-transistor amplifier circuit having one or more features described above. In some embodiments, the front-end system 803 may comprise one or both the dual-transistor amplifier circuit 800 and dual-transistor amplifier circuit 1700 with respect to FIGS. 8A and 17A.

The mobile device 820 can be used communicate using a wide variety of communications technologies, including, but not limited to, 2G, 3G, 4G (including LTE, LTE-Advanced, and LTE-Advanced Pro), 5G NR, WLAN (for instance, WiFi), WPAN (for instance, Bluetooth and ZigBee), WMAN (for instance, WiMax), and/or GPS technologies.

The transceiver 802 generates RF signals for transmission and processes incoming RF signals received from the antennas 804. It will be understood that various functionalities associated with the transmission and receiving of RF signals can be achieved by one or more components that are collectively represented in FIG. 11 as the transceiver 802. In one example, separate components (for instance, separate circuits or dies) can be provided for handling certain types of RF signals. Such separate transceiver circuits or dies can receive separate RF split signals from the front-end systems implemented in accordance with the teachings herein.

The front-end system 803 aids in conditioning signals transmitted to and/or received from the antennas 804. In the illustrated embodiment, the front-end system 803 includes antenna tuning circuitry 810, power amplifiers (PAS) 811, low noise amplifiers (LNAs) 812, filters 813, switches 814, and signal splitting/combining circuitry 815. The front-end system 803 can be implemented in accordance with any of the embodiments herein.

With continuing reference to FIG. 11, the front-end system 803 can provide a number of functionalities, including, but not limited to, amplifying signals for transmission, amplifying received signals, filtering signals, switching between different bands, switching between different power modes, switching between transmission and receiving modes, duplexing of signals, multiplexing of signals (for instance, diplexing or triplexing), or some combination thereof.

In certain implementations, the mobile device 820 supports carrier aggregation, thereby providing flexibility to increase peak data rates. Carrier aggregation can be used for both Frequency Division Duplexing (FDD) and Time Division Duplexing (TDD), and may be used to aggregate a plurality of carriers or channels. Carrier aggregation includes contiguous aggregation, in which contiguous carriers within the same operating frequency band are aggregated. Carrier aggregation can also be non-contiguous, and can include carriers separated in frequency within a common band or in different bands.

The antennas 804 can include antennas used for a wide variety of types of communications. For example, the antennas 804 can include antennas for transmitting and/or receiving signals associated with a wide variety of frequencies and communications standards.

In certain implementations, the antennas 804 support MIMO communications and/or switched diversity communications. For example, MIMO communications use multiple antennas for communicating multiple data streams over a single radio frequency channel. MIMO communications benefit from higher signal to noise ratio, improved coding, and/or reduced signal interference due to spatial multiplexing differences of the radio environment. Switched diversity refers to communications in which a particular antenna is selected for operation at a particular time. For example, a switch can be used to select a particular antenna from a group of antennas based on a variety of factors, such as an observed bit error rate and/or a signal strength indicator.

The mobile device 820 can operate with beamforming in certain implementations. For example, the front-end system 803 can include amplifiers having controllable gain and phase shifters having controllable phase to provide beam formation and directivity for transmission and/or reception of signals using the antennas 804. For example, in the context of signal transmission, the amplitude and phases of the transmit signals provided to the antennas 804 are controlled such that radiated signals from the antennas 804 combine using constructive and destructive interference to generate an aggregate transmit signal exhibiting beam-like qualities with more signal strength propagating in a given direction. In the context of signal reception, the amplitude and phases are controlled such that more signal energy is received when the signal is arriving to the antennas 804 from a particular direction. In certain implementations, the antennas 804 include one or more arrays of antenna elements to enhance beamforming.

The baseband system 801 is coupled to the user interface 807 to facilitate processing of various user input and output (I/O), such as voice and data. The baseband system 801 provides the transceiver 802 with digital representations of transmit signals, which the transceiver 802 processes to generate RF signals for transmission. The baseband system 801 also processes digital representations of received signals provided by the transceiver 802. As shown in FIG. 11, the baseband system 801 is coupled to the memory 806 to facilitate operation of the mobile device 820.

The memory 806 can be used for a wide variety of purposes, such as storing data and/or instructions to facilitate the operation of the mobile device 820 and/or to provide storage of user information.

The power management system 805 provides a number of power management functions of the mobile device 820. In certain implementations, the power management system 805 includes a PA supply control circuit that controls the supply voltages of the power amplifiers 811. For example, the power management system 805 can be configured to change the supply voltage(s) provided to one or more of the power amplifiers 811 to improve efficiency, such as power added efficiency (PAE).

As shown in FIG. 11, the power management system 805 receives a battery voltage from the battery 808. The battery 808 can be any suitable battery for use in the mobile device 820, including, for example, a lithium-ion battery.

### Applications

Some of the embodiments described above have provided examples in connection with mobile devices. However, the principles and advantages of the embodiments can be used for a wide range of RF communication systems. Examples of such RF communication systems include, but are not limited to, mobile phones, tablets, base stations, network access points, customer-premises equipment (CPE), laptops, and wearable electronics.

### CONCLUSION

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “may,” “could,” “might,” “can,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings of the invention provided herein can be applied to other systems, not necessarily the system described above. The elements and acts of the various embodiments described above can be combined to provide further embodiments.

While certain embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

What is claimed is:

1. A radio frequency amplifier comprising:
a first field effect transistor configured to receive a radio frequency input signal and provide a first intermediate amplified signal on a first output of the first field effect transistor, the first field effect transistor having a first source and a first drain electrically biased at a first drain bias voltage;
a second field effect transistor configured to receive the radio frequency input signal and provide a second intermediate amplified signal on a second output of the second field effect transistor, the second field effect transistor having a second source and a second drain electrically biased at a second drain bias voltage different from the first drain bias voltage; and
an output port coupled to first output and to the second output to provide a combined output signal in response to first intermediate amplified signal and the second intermediate amplified signal.

2. The radio frequency amplifier of claim 1, wherein a first gate of the first field effect transistor and a second gate of the second field effect transistor are biased at a common gate voltage with respect to the first and second sources, respectively.

3. The radio frequency amplifier of claim 1, wherein a difference between the first and second drain bias voltages is equal to a predetermined offset drain voltage.

4. The radio frequency amplifier of claim 3, where in one or both the first drain bias voltage and the offset drain voltage are configured to reduce a third order transconductance of the radio frequency amplifier compared to a third order transconductance of the first and second field effect transistor.

5. The radio frequency amplifier of claim 3, wherein the offset drain voltage is constant during operation of the radio frequency amplifier.

6. The radio frequency amplifier of claim 2, wherein variation of amplitude of a third order intermodulation frequency component of the combined output signal with respect to variation of the common gate bias voltage includes a dip having a minimum.

7. The radio frequency amplifier of claim 6, wherein the minimum comprises an absolute minimum within an operational range of the common gate bias voltage.

8. The radio frequency amplifier of claim 1, wherein a first source the first field effect transistor and a second source of the second field effect transistor are electrically connected to a common reference voltage.

9. The radio frequency amplifier of claim 1, wherein the combined output signal is a sum of the first and second intermediate amplified signals.

10. The radio frequency amplifier of claim 1, wherein a first source of the first field effect transistor and a second source of the second field effect transistor are electrically coupled to the output port.

11. The radio frequency amplifier of claim 1, wherein a first drain of the first field effect transistor and a second drain of the second field effect transistor are electrically coupled to the output port.

12. The radio frequency amplifier of claim 1, wherein the radio frequency input signal is received through an input port capacitively coupled to a first gate of the first field effect transistor and a second gate of the second field effect transistor.

13. The radio frequency amplifier of claim 1 wherein the first field effect transistor is substantially identical to the second field effect transistor.

14. The radio frequency amplifier of claim 1, wherein at least one parameter of the first field effect transistor is different from that of the second field effect transistor.

15. The radio frequency amplifier of claim 1, wherein the first and second transistors comprise junction field effect transistors.

16. A radio frequency front-end system including the radio frequency amplifier of claim 1.

17. A mobile device including the radio frequency front-end system of claim 16.

18. The radio frequency amplifier of claim 1, wherein the first and second field effect amplifiers are connected in a parallel configuration.

19. A mobile device comprising:
a radio frequency amplifier comprising:
a first field effect transistor configured to receive a radio frequency input signal and provide a first intermediate amplified signal on a first output of the first field effect transistor, the first field effect transistor having a first source and a first drain electrically biased at a first drain bias voltage with respect to the first source;
a second field effect transistor configured to receive the radio frequency input signal and provide a second intermediate amplified signal on a second output of the second field effect transistor, the second field effect transistor having a second source and a second drain electrically biased at a second drain bias voltage different from the first drain bias voltage; and
an output port coupled to first output and to the second output to provide a combined output signal in response to first intermediate amplified signal and the second intermediate amplified signal.

20. The mobile device of claim 19 wherein a first gate of the first field effect transistor and a second gate of the second field effect transistor are biased at a common gate voltage with respect to the first and second sources, respectively.
